(19) United States
(12) Patent Application Publication
(10) Pub. No.: US 2024/0268180 A1
(43) Pub. Date: Aug. 8, 2024

(54) DISPLAY APPARATUS, DISPLAY MODULE, ELECTRONIC DEVICE, AND FABRICATION METHOD OF DISPLAY APPARATUS

(71) Applicant: Semiconductor Energy Laboratory Co., Ltd., Kanagawa (JP)

(72) Inventors: Takayuki IKEDA, Atsugi (JP); Kenichi OKAZAKI, Atsugi (JP); Yoshiaki OIKAWA, Atsugi (JP); Natsuko TAKASE, Isehara (JP); Kensuke YOSHIZUMI, Atsugi (JP)

(21) Appl. No.: 18/566,682

(22) PCT Filed: May 27, 2022
(86) PCT No.: PCT/IB2022/054989

§ 371 Date: Dec. 4, 2023

(30) Foreign Application Priority Data
Jun. 8, 2021 (JP) 2021-096208

(51) Int. Cl. H10K 59/38; H10K 50/13; H10K 50/19; H10K 71/60

(52) U.S. Cl. CPC H10K 59/38; H10K 50/13; H10K 50/19; H10K 71/60

(57) ABSTRACT

A display apparatus with high resolution or high definition is provided. The display apparatus includes a first light-emitting device, a second light-emitting device, a first insulating layer, a first coloring layer, and a second coloring layer. The first light-emitting device includes a first pixel electrode, a first EL layer, and a common electrode that are stacked in this order. The second light-emitting device includes a second pixel electrode, a second EL layer, and the common electrode that are stacked in this order. The first coloring layer overlaps with the first light-emitting device. The second coloring layer transmitting light of a color different from a color of light transmitted by the first coloring layer overlaps with the second light-emitting device. The first EL layer and the second EL layer have the same structure and are separated from each other. An end portion of the first EL layer is positioned over the first pixel electrode. An end portion of the second EL layer is positioned over the second pixel electrode. The first insulating layer covers side surfaces of the first pixel electrode, the second pixel electrode, the first EL layer, and the second EL layer. The common electrode is positioned over the first insulating layer.

### TECHNICAL FIELD

One embodiment of the present invention relates to a display apparatus, a display module, and an electronic device. One embodiment of the present invention relates to a method for fabricating a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a driving method thereof, and a manufacturing method thereof.

### BACKGROUND ART

Recent display apparatuses have been expected to be applied to a variety of uses. Usage examples of large-sized display apparatuses include a television device for home use (also referred to as TV or television receiver), digital signage, and a PID (Public Information Display). In addition, a smartphone and a tablet terminal each including a touch panel, and the like, are being developed as portable information terminals.

Furthermore, higher-resolution display apparatuses have been required. For example, devices for virtual reality (VR), augmented reality (AR), substitutional reality (SR), or mixed reality (MR) are given as devices required by high-resolution display apparatuses and have been actively developed.

Light-emitting apparatuses including light-emitting devices (also referred to as light-emitting elements) have been developed as display apparatuses, for example. Light-emitting devices (also referred to as EL devices or EL elements) utilizing electroluminescence (hereinafter referred to as EL) have features such as ease of reduction in thickness and weight, high-speed response to input signals, and driving with a constant DC voltage power source, and have been used in display apparatuses.
Patent Document 1 discloses a display apparatus using an organic EL device (also referred to as organic EL element) for VR.
Non-Patent Document 1 discloses a method for manufacturing an organic optoelectronic device using standard UV photolithography.

### REFERENCES

### Patent Document

[Patent Document 1] PCT International Publication No. 2018/087625

### Non-Patent Document

[Non-Patent Document 1] B. Lamprecht et al., “Organic optoelectronic device fabrication using standard UV photolithography” phys. stat. sol. (RRL) 2, No. 1, pp. 16-18 (2008)

### SUMMARY OF THE INVENTION

### Problems to be Solved by the Invention

An object of one embodiment of the present invention is to provide a high-resolution display apparatus. An object of one embodiment of the present invention is to provide a high-definition display apparatus. An object of one embodiment of the present invention is to provide a highly reliable display apparatus.

An object of one embodiment of the present invention is to provide a method for fabricating a high-resolution display apparatus. An object of one embodiment of the present invention is to provide a method for fabricating a high-definition display apparatus. An object of one embodiment of the present invention is to provide a method for fabricating a highly reliable display apparatus. An object of one embodiment of the present invention is to provide a method for fabricating a display apparatus with a high yield.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display apparatus including a first light-emitting device, a second light-emitting device, a first insulating layer, a first coloring layer, and a second coloring layer. The first light-emitting device includes a first pixel electrode, a first EL layer over the first pixel electrode, and a common electrode over the first EL layer. The second light-emitting device includes a second pixel electrode, a second EL layer over the second pixel electrode, and the common electrode over the second EL layer. The first coloring layer overlaps with the first light-emitting device. The second coloring layer overlaps with the second light-emitting device. The second coloring layer and the first coloring layer transmit light of different colors. The first EL layer and the second EL layer have the same structure and are separated from each other. An end portion of the first EL layer is positioned over the first pixel electrode. An end portion of the second EL layer is positioned over the second pixel electrode. The first insulating layer covers side surfaces of the first pixel electrode, the second pixel electrode, the first EL layer, and the second EL layer. The common electrode is positioned over the first insulating layer.

Preferably, the first EL layer includes a first light-emitting unit over the first pixel electrode, a first charge-generation layer over the first light-emitting unit, and a second light-emitting unit over the first charge-generation layer, and the second EL layer includes a third light-emitting unit over the second pixel electrode, a second charge-generation layer over the third light-emitting unit, and a fourth light-emitting unit over the second charge-generation layer.

The above display apparatus preferably includes a second insulating layer. Preferably, the first insulating layer contains an inorganic material, and the second insulating layer contains an organic material and overlaps with the side surfaces of the first pixel electrode, the second pixel electrode, the first EL layer, and the second EL layer with the first insulating layer therebetween.

Preferably, the first light-emitting device includes a common layer between the first EL layer and the common electrode, the second light-emitting device includes the common layer between the second EL layer and the common electrode, and the common layer includes at least one of a hole-injection layer, a hole-transport layer, a hole-blocking layer, an electron-blocking layer, an electron-transport layer, and an electron-injection layer.

The first EL layer preferably contains a first light-emitting material emitting blue light and a second light-emitting material emitting light with a longer wavelength than blue light.

The first insulating layer is preferably in contact with the side surface of the first pixel electrode and the side surface of the second pixel electrode.

One embodiment of the present invention is a display module including the display apparatus having any of the above-described structures and is, for example, a display module provided with a connector such as a flexible printed circuit (hereinafter referred to as an FPC) or a TCP (Tape Carrier Package), or a display module on which an integrated circuit (IC) is mounted by a COG (Chip On Glass) method, a COF (Chip On Film) method, or the like.

One embodiment of the present invention is an electronic device including the above-described display module and at least one of a housing, a battery, a camera, a speaker, and a microphone.

One embodiment of the present invention is a method for fabricating a display apparatus, including: forming a first pixel electrode and a second pixel electrode over an insulating surface; forming an EL film over the first pixel electrode and the second pixel electrode; forming a sacrificial film over the EL film; processing the EL film and the sacrificial film to form a first EL layer having an end portion over the first pixel electrode, a first sacrificial layer over the first EL layer, a second EL layer having an end portion over the second pixel electrode, and a second sacrificial layer over the second EL layer; forming a first insulating film covering at least a side surface of the first pixel electrode, a side surface of the second pixel electrode, a side surface of the first EL layer, a side surface of the second EL layer, a side surface and a top surface of the first sacrificial layer, and a side surface and a top surface of the second sacrificial layer; processing the first insulating film to form a first insulating layer covering at least the side surface of the first pixel electrode, the side surface of the second pixel electrode, the side surface of the first EL layer, and the side surface of the second EL layer; removing the first sacrificial layer and the second sacrificial layer; forming a common electrode over the first EL layer and the second EL layer; and placing, over the common electrode, a first coloring layer overlapping with the first EL layer and a second coloring layer overlapping with the second EL layer.

Preferably, the first insulating film is formed using an inorganic material, the second insulating film is formed using an organic material over the first insulating film after the first insulating film is formed, and the second insulating film is processed to form a second insulating layer overlapping with the side surfaces of the first pixel electrode, the second pixel electrode, the first EL layer, and the second EL layer with the first insulating film therebetween.

A photosensitive resin is preferably used as the organic material.

Before the common electrode is formed, at least one of a hole-injection layer, a hole-transport layer, a hole-blocking layer, an electron-blocking layer, an electron-transport layer, and an electron-injection layer is preferably formed as a common layer over the first EL layer and the second EL layer.

### Effect of the Invention

One embodiment of the present invention can provide a high-resolution display apparatus. One embodiment of the present invention can provide a high-definition display apparatus. One embodiment of the present invention can provide a highly reliable display apparatus.

One embodiment of the present invention can provide a method for fabricating a high-resolution display apparatus. One embodiment of the present invention can provide a method for fabricating a high-definition display apparatus. One embodiment of the present invention can provide a method for fabricating a highly reliable display apparatus. One embodiment of the present invention can provide a method for fabricating a display apparatus with a high yield.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a display apparatus. FIG. 1B is a cross-sectional view illustrating an example of the display apparatus.

FIG. 2A to FIG. 2C are cross-sectional views illustrating examples of a display apparatus.

FIG. 3A to FIG. 3C are cross-sectional views illustrating examples of a display apparatus.

FIG. 4A to FIG. 4C are cross-sectional views illustrating examples of a display apparatuses.

FIG. 5A to FIG. 5F are cross-sectional views illustrating examples of a display apparatus.

FIG. 6A to FIG. 6D are cross-sectional views illustrating an example of a method for fabricating a display apparatus.

FIG. 7A to FIG. 7C are cross-sectional views illustrating the example of a method for fabricating a display apparatus.

FIG. 8A to FIG. 8F are top views illustrating examples of a pixel.

FIG. 9A to FIG. 9H are top views illustrating examples of a pixel.

FIG. 10A to FIG. 10J are top views illustrating examples of a pixel.

FIG. 11 is a perspective view illustrating an example of a display apparatus.

FIG. 12A is a cross-sectional view illustrating an example of a display apparatus. FIG. 12B and

FIG. 12C are cross-sectional views illustrating examples of transistors.

FIG. 13 is a cross-sectional view illustrating an example of a display apparatus.

FIG. 14A to FIG. 14D are cross-sectional views illustrating examples of a display apparatus.

FIG. 15A and FIG. 15B are perspective views illustrating an example of a display module.

FIG. 16A to FIG. 16C are cross-sectional views illustrating an example of a display apparatus.

FIG. 17 is a cross-sectional view illustrating an example of a display apparatus.

FIG. 18 is a cross-sectional view illustrating an example of a display apparatus.

FIG. 19 is a cross-sectional view illustrating an example of a display apparatus.

FIG. 20 is a cross-sectional view illustrating an example of a display apparatus.

FIG. 21A to FIG. 21F are diagrams illustrating structure examples of a light-emitting device.

FIG. 22A to FIG. 22D are diagrams illustrating examples of electronic devices.

FIG. 23A to FIG. 23F are diagrams illustrating examples of electronic devices.

FIG. 24A to FIG. 24G are diagrams illustrating examples of electronic devices.

FIG. 25A to FIG. 25F are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the structures of the invention described below, the same portions or portions having similar functions are denoted by the same reference numerals in different drawings, and description of such portions is not repeated. The same hatching pattern is applied to portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

In this specification and the like, a device fabricated using a metal mask or an FMM (fine metal mask, a high-resolution metal mask) may be referred to as a device having an FMM structure or a device having an MM (metal mask) structure. In this specification and the like, a device fabricated without using a metal mask or an FMM may be referred to as a device having an MML (metal maskless) structure.

### Embodiment 1

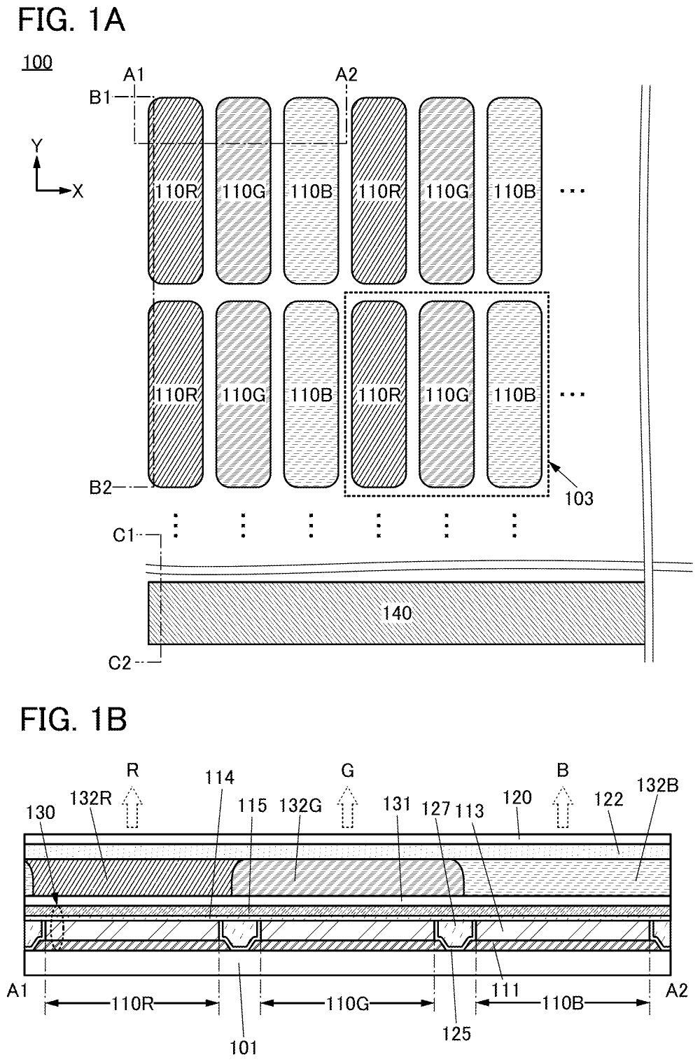

In this embodiment, a display apparatus of one embodiment of the present invention and a fabrication method thereof are described with reference to FIG. 1 to FIG. 10.

The display apparatus of one embodiment of the present invention includes a first light-emitting device including a first EL layer, a second light-emitting device including a second EL layer, a first coloring layer overlapping with the first light-emitting device, and a second coloring layer overlapping with the second light-emitting device. The first EL layer and the second EL layer have the same structure and are separated from each other. The first coloring layer and the second coloring layer transmit light of different colors.

In the display apparatus of one embodiment of the present invention, subpixels include light-emitting devices including EL layers having the same structure, and coloring layers overlapping with the light-emitting devices. Coloring layers transmitting visible light of different colors are provided for subpixels, whereby full-color display can be performed.

In the case where light-emitting devices including EL layers having the same structure are used in a plurality of subpixels, it is not necessary to form light-emitting layers separately for the subpixels. Thus, a layer other than a pixel electrode included in the light-emitting device (e.g., a light-emitting layer) can be common between (can be shared by) a plurality of subpixels. However, some layers included in the light-emitting device have relatively high conductivity; when such a layer having high conductivity is provided to be shared by a plurality of subpixels, leakage current might be generated between the subpixels. Particularly when the increase in resolution or aperture ratio of a display apparatus reduces the distance between subpixels, the leakage current might become too large to ignore and cause a decrease in display quality of the display apparatus, for example. In view of this, in the display apparatus of one embodiment of the present invention, at least one layer included in the EL layer is formed in an island shape in each subpixel. When at least one layer included in the EL layer is separated between subpixels, generation of crosstalk between adjacent subpixels can be inhibited. This enables the display apparatus to achieve both high resolution and high display quality.

For example, an island-shaped light-emitting layer can be formed by a vacuum evaporation method using a metal mask. However, this method causes a deviation from the designed shape and position of an island-shaped light-emitting layer due to various influences such as the low accuracy of the metal mask position, the positional deviation between the metal mask and a substrate, a warp of the metal mask, and an expansion of outline of the formed film due to vapor scattering or the like; accordingly, it is difficult to achieve high resolution and a high aperture ratio of the display apparatus. In addition, the outline of the layer may blur during vapor deposition, whereby the thickness of an end portion may be reduced. That is, the thickness of the island-shaped light-emitting layer may vary from area to area. In the case of fabricating a display apparatus with a large size, high definition, or high resolution, the manufacturing yield might be reduced because of low dimensional accuracy of the metal mask and deformation due to heat or the like.

In view of this, in fabrication of the display apparatus of one embodiment of the present invention, pixel electrodes are formed for the respective subpixels, and then a light-emitting layer is formed across the pixel electrodes. After that, the light-emitting layer is processed by a photolithography method, for example, so that one island-shaped light-emitting layer is formed per pixel electrode. Thus, the light-emitting layer can be divided into island-shaped light-emitting layers for the respective subpixels.

In the case of processing the light-emitting layer into an island shape, a structure is possible where processing is performed by a photolithography method directly on the light-emitting layer. In the case of this structure, damage to the light-emitting layer (e.g., processing damage) might significantly degrade the reliability. In view of the above, in fabrication of the display apparatus of one embodiment of the present invention, a sacrificial layer (also referred to as a mask layer) or the like is preferably formed over a layer above the light-emitting layer (e.g., a carrier-transport layer or a carrier-injection layer, and specifically an electron-transport layer or an electron-injection layer), followed by the processing of the light-emitting layer into an island shape. Such a method provides a highly reliable display apparatus.

As described above, in the method for fabricating a display apparatus of one embodiment of the present invention, the island-shaped light-emitting layers are formed not by using a metal mask having a fine pattern but by processing a light-emitting layer formed over the entire surface. Specifically, the size of the island-shaped light-emitting layer is obtained by division and scale down of the light-emitting layer by a photolithography method or the like. Thus, the size of the island-shaped light-emitting layer can be made smaller than the size of the layers formed using a metal mask. Accordingly, a high-resolution display apparatus or a display apparatus with a high aperture ratio, which has been difficult to achieve, can be achieved.

The processing of the light-emitting layer by a photolithography method is preferably performed a small number of times, in which case the manufacturing cost can be reduced and the manufacturing yield can be improved. In the method for fabricating the display apparatus of one embodiment of the present invention, the number of times of processing of the light-emitting layer by a photolithography method can be one; thus, the display apparatus can be fabricated with high yield.

It is difficult to set the interval between adjacent light-emitting devices to less than 10 μm with a formation method using a metal mask, for example; however, with the above method, the distance can be decreased to less than 10 μm, less than or equal to 5 μm, less than or equal to 3 μm, less than or equal to 2 μm, or less than or equal to 1 μm. Furthermore, with the use of a light exposure apparatus for LSI, for example, the distance between adjacent light-emitting devices can be shortened to less than or equal to 500 nm, less than or equal to 200 nm, less than or equal to 100 nm, or less than or equal to 50 nm. Accordingly, the area of a non-light-emitting region that could exist between two light-emitting devices can be significantly reduced, and the aperture ratio can be close to 100%. For example, the aperture ratio is higher than or equal to 50%, higher than or equal to 60%, higher than or equal to 70%, higher than or equal to 80%, or higher than or equal to 90%; that is, an aperture ratio lower than 100% can be achieved.

Furthermore, a pattern of the light-emitting layer itself (also referred to as a processing size) can be made much smaller than that in the case of using a metal mask. For example, in the case of using a metal mask for forming light-emitting layers separately, a variation in the thickness occurs between the center and the edge of the light-emitting layer, which causes a reduction in an effective area that can be used as a light-emitting region with respect to the area of the light-emitting layer. In contrast, in the above fabrication method, a film formed to have a uniform thickness is processed, so that island-shaped light-emitting layers can be formed to have a uniform thickness. Accordingly, even in a fine pattern, almost the whole area can be used as a light-emitting region. Thus, a display apparatus having both high resolution and a high aperture ratio can be fabricated.

The use of the method for fabricating a display apparatus of one embodiment of the present invention enables a structure where an end portion of an EL layer is positioned over a pixel electrode. In this structure, the EL layer is not provided between adjacent pixel electrodes, which can inhibit generation of leakage current between adjacent light-emitting devices through the EL layer. Moreover, thinning of the EL layer at and around the end portion of the pixel electrode can also be inhibited, allowing a uniform thickness of the EL layer.

In the method for fabricating a display apparatus of one embodiment of the present invention, preferably, a layer including a light-emitting layer (that can be referred to as an EL layer or part of an EL layer) is formed over the entire surface, and then a sacrificial layer is formed over the EL layer. Then, a resist mask is formed over the sacrificial layer, and the EL layer and the sacrificial layer are processed using the resist mask, whereby an island-shaped EL layer is preferably formed.

Provision of a sacrificial layer over an EL layer can reduce damage to the EL layer during a fabrication step of the display apparatus and increase the reliability of the light-emitting device.

The island-shaped EL layer includes at least the light-emitting layer and preferably includes a plurality of layers. Specifically, one or more layers are preferably provided over the light-emitting layer. A layer provided between the light-emitting layer and the sacrificial layer can inhibit the light-emitting layer from being exposed on the outermost surface during the fabrication process of the display apparatus and can reduce damage to the light-emitting layer. Thus, the reliability of the light-emitting device can be increased. Thus, the island-shaped EL layer preferably includes the light-emitting layer and a carrier-transport layer (an electron-transport layer or a hole-transport layer) over the light-emitting layer.

Note that in the light-emitting device, all layers included in the EL layer are not necessarily formed in island shapes, and some layers can be shared by (are common between) a plurality of light-emitting devices. Examples of layers in the EL layer include a light-emitting layer, carrier-injection layers (a hole-injection layer and an electron-injection layer), carrier-transport layers (a hole-transport layer and an electron-transport layer), carrier-blocking layers (a hole-blocking layer and an electron-blocking layer), and the like. In the method for fabricating the display apparatus of one embodiment of the present invention, some of the layers included in the EL layer are formed in an island shape for each subpixel, and then, at least part of the sacrificial layer is removed and the other layer(s) included in the EL layer (e.g., a carrier-injection layer) and a common electrode (also referred to as an upper electrode) can be formed to be shared by the plurality of light-emitting devices.

In contrast, the carrier-injection layer is often a layer having relatively high conductivity in the EL layer. Therefore, when the carrier-injection layer is in contact with the side surface of the island-shaped EL layer or the side surface of the pixel electrode, the light-emitting device might be short-circuited. Note that also in the case where the carrier-injection layer is provided in an island shape and the common electrode is formed to be shared by the plurality of light-emitting devices, the light-emitting device might be short-circuited when the common electrode is in contact with the side surface of the EL layer or the side surface of the pixel electrode.

Thus, the display apparatus of one embodiment of the present invention includes an insulating layer covering at least the side surface of the island-shaped light-emitting layer. Note that here, the side surface of the island-shaped light-emitting layer refers to the plane that is not parallel to the substrate (or the surface where the light-emitting layer is formed) among the interfaces between the island-shaped light-emitting layer and other layers. The side surface is not necessarily one of a flat plane and a curved plane in an exactly mathematical perspective.

Thus, at least one layer in the island-shaped EL layer and the pixel electrode can be inhibited from being in contact with the carrier-injection layer or the common electrode. Hence, a short circuit of the light-emitting device is inhibited, and the reliability of the light-emitting device can be increased.

Moreover, providing the insulating layer can fill the space between adjacent island-shaped EL layers; hence, the formation surface of a layer (e.g., the carrier-injection layer or the common electrode) provided over the island-shaped EL layer has less unevenness and can be flatter. Consequently, the coverage of the carrier-injection layer or the common electrode can be increased. As a result, disconnection of the common electrode can be prevented.

Note that in this specification and the like, disconnection refers to a phenomenon in which a layer, a film, or an electrode is split because of the shape of the formation surface (e.g., a level difference).

The insulating layer can be provided in contact with the island-shaped EL layer. Thus, the EL layer can be prevented from being peeled off. Close contact between the insulating layer and the island-shaped EL layers has an effect of fixing or bonding adjacent island-shaped EL layers to each other. Furthermore, the insulating layer inhibits moisture from entering the interface between the pixel electrode and the EL layer, so that peeling of the EL layer can be prevented. Thus, the reliability of the light-emitting device can be increased. The fabrication yield of the light-emitting device can be increased.

The insulating layer preferably has a function of a barrier insulating layer against at least one of water and oxygen. Alternatively, the insulating layer preferably has a function of inhibiting diffusion of at least one of water and oxygen. Alternatively, the insulating layer preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a targeted substance (also referred to as having low permeability). Alternatively, a barrier property refers to a function of capturing or fixing (also referred to as gettering) a targeted substance.

With the use of an insulating layer having a function of the barrier insulating layer or a gettering function, entry of impurities (typically, at least one of water and oxygen) that might diffuse into the light-emitting devices from the outside can be inhibited. With this structure, a highly reliable light-emitting device and a highly reliable display apparatus can be provided.

The display apparatus of one embodiment of the present invention includes a pixel electrode functioning as an anode; an island-shaped hole-injection layer, an island-shaped hole-transport layer, an island-shaped light-emitting layer, and an island-shaped electron-transport layer that are provided in this order over the pixel electrode; an insulating layer provided so as to cover the side surfaces of the pixel electrode, the hole-injection layer, the hole-transport layer, the light-emitting layer, and the electron-transport layer; an electron-injection layer provided over the electron-transport layer; and a common electrode that is provided over the electron-injection layer and functions as a cathode.

Alternatively, the display apparatus of one embodiment of the present invention includes a pixel electrode functioning as a cathode; an island-shaped electron-injection layer, an island-shaped electron-transport layer, an island-shaped light-emitting layer, and an island-shaped hole-transport layer that are provided in this order over the pixel electrode; an insulating layer provided so as to cover the side surfaces of the pixel electrode, the electron-injection layer, the electron-transport layer, the light-emitting layer, and the hole-transport layer; a hole-injection layer provided over the hole-transport layer; and a common electrode that is provided over the hole-injection layer and functions as an anode.

Alternatively, the display apparatus of one embodiment of the present invention includes a pixel electrode, a first light-emitting unit over the pixel electrode, a charge-generation layer (also referred to as an intermediate layer) over the first light-emitting unit, a second light-emitting unit over the charge-generation layer, an insulating layer provided to cover side surfaces of the first light-emitting unit, the charge-generation layer, and the second light-emitting unit, and a common electrode provided over the second light-emitting unit. Note that the light-emitting devices of different colors may include a common layer between the second light-emitting unit and the common electrode.

The hole-injection layer, the electron-injection layer, and the charge-generation layer, for example, often have relatively high conductivity in the EL layer. Since the side surfaces of these layers are covered with the insulating layer in the display apparatus of one embodiment of the present invention, these layers can be inhibited from being in contact with the common electrode or the like. Hence, a short circuit of the light-emitting device is inhibited, and the reliability of the light-emitting device can be increased.

The insulating layer covering the side surface of the island-shaped EL layer may have a single-layer structure or a stacked-layer structure.

For example, an insulating layer having a single-layer structure using an inorganic material can be used as a protective insulating layer for the EL layer. In this way, the reliability of the display apparatus can be improved.

In the case where the insulating layer has a stacked-layer structure, the first layer of the insulating layer is preferably formed using an inorganic insulating material because it is formed in contact with the EL layer. In particular, the first layer of the insulating layer is preferably formed by an atomic layer deposition (ALD) method, by which damage due to deposition is small. Alternatively, an inorganic insulating layer is preferably formed by a sputtering method, a chemical vapor deposition (CVD) method, or a plasma-enhanced chemical vapor deposition (PECVD) method, which have higher deposition rate than an ALD method. In that case, a highly reliable display apparatus can be fabricated with high productivity. The second layer of the insulating layer is preferably formed using an organic material to fill a depressed portion formed by the first layer of the insulating layer.

For example, an aluminum oxide film formed by an ALD method can be used as the first layer of the insulating layer, and an organic resin film can be used as the second layer of the insulating layer.

In the case where the side surface of the EL layer and the organic resin film are in direct contact with each other, the EL layer might be damaged by an organic solvent or the like that might be contained in the organic resin film. When an inorganic insulating film such as an aluminum oxide film by an ALD method is used as the first layer of the insulating layer, a structure in which the organic resin film and the side surface of the EL layer are not in direct contact with each other can be obtained. Thus, the EL layer can be inhibited from being dissolved by the organic solvent, for example.

In the display apparatus of one embodiment of the present invention, it is not necessary to provide an insulating layer that covers the end portion of the pixel electrode between the pixel electrode and the EL layer; thus, the distance between adjacent light-emitting devices can be made extremely short. Thus, a display apparatus with higher resolution or higher definition can be achieved. In addition, a mask for forming the insulating layer is not needed, which leads to a reduction in manufacturing cost of the display apparatus.

Furthermore, light emitted by the EL layer can be extracted efficiently with a structure where an insulating layer covering the end portion of the pixel electrode is not provided between the pixel electrode and the EL layer, i.e., a structure where an insulating layer is not provided between the pixel electrode and the EL layer. Therefore, the display apparatus of one embodiment of the present invention can significantly reduce the viewing angle dependence. A reduction in the viewing angle dependence leads to an increase in visibility of an image on the display apparatus. For example, in the display apparatus of one embodiment of the present invention, the viewing angle (the maximum angle with a certain contrast ratio maintained when the screen is seen from an oblique direction) can be more than or equal to 100° and less than 180°, preferably more than or equal to 150° and less than or equal to 170°. Note that the viewing angle refers to that in both the vertical direction and the horizontal direction.

### Structure Example of Display Apparatus

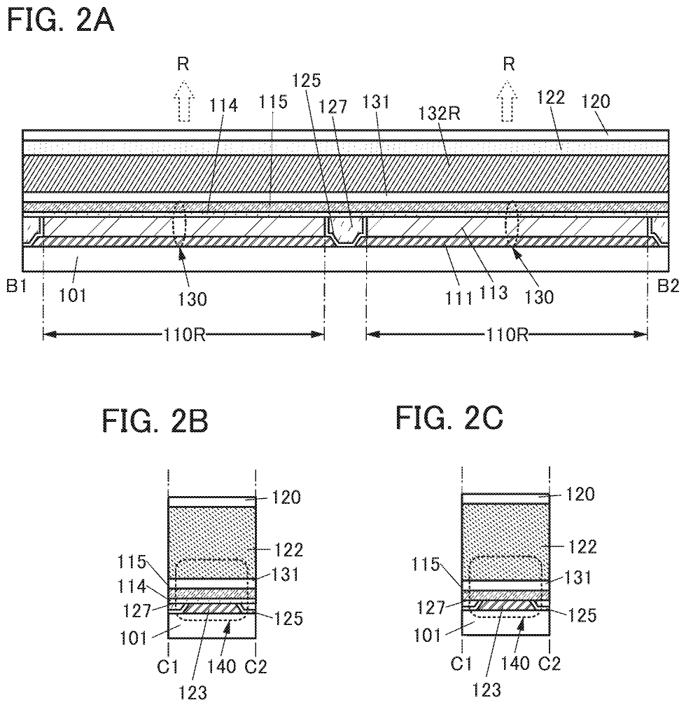

FIG. 1 and FIG. 2 illustrate display apparatuses of one embodiment of the present invention.

FIG. 1A is a top view of a display apparatus 100. The display apparatus 100 includes a display portion in which a plurality of pixels 103 are arranged, and a connection portion 140 outside the display portion. A plurality of subpixels are arranged in matrix in the display portion. FIG. 1A illustrates subpixels arranged in two rows and six columns, which form pixels in two rows and two columns. The connection portion 140 can also be referred to as a cathode contact portion.

The pixel 103 illustrated in FIG. 1A employs stripe arrangement. The pixel 103 illustrated in FIG. 1A is composed of three subpixels: a subpixel 110R, a subpixel 110G, and a subpixel 110B.

The subpixel 110R emits red light, the subpixel 110G emits green light, and the subpixel 110B emits blue light. Note that in this embodiment, subpixels of three colors of red (R), green (G), and blue (B) are described as an example; however, subpixels of three colors of yellow (Y), cyan (C), and magenta (M) may be used, for example. The number of types of subpixels is not limited to three and may be four or more. As four subpixels, subpixels of four colors of R, G, B, and white (W), subpixels of four colors of R, G, B, and Y, or four subpixels of R, G, B, and infrared light (IR) can be given, for example.

The top surface shapes of the subpixels illustrated in FIG. 1A correspond to the top surface shapes of light-emitting regions.

The range of the circuit layout for forming the subpixels is not limited to the range of the subpixels illustrated in FIG. 1A and may be placed outside the subpixels. For example, some or all of transistors included in the subpixel 110R may be positioned outside the range of the subpixel 110R illustrated in FIG. 1A. For example, transistors included in the subpixel 110R may include a portion positioned within the range of the subpixel 110G, or may include a portion positioned within the range of the subpixel 110B.

In this specification and the like, the row direction is referred to as X direction and the column direction is referred to as Y direction in some cases. The X direction and the Y direction intersect with each other and are, for example, orthogonal to each other (see FIG. 1A).

FIG. 1A illustrates an example in which subpixels of different colors are arranged in the X direction and subpixels of the same color are arranged in the Y direction.

Although the top view of FIG. 1A illustrates an example in which the connection portion 140 is positioned in the lower side of the display portion, one embodiment of the present invention is not limited thereto. The connection portion 140 may be provided in at least one of the upper side, the right side, the left side, and the lower side of the display portion in the top view, and may be provided so as to surround the four sides of the display portion. The top surface shape of the connection portion 140 can be a belt-like shape, an L shape, a U shape, a frame-like shape, or the like. The number of the connection portions 140 can be one or more.

FIG. 1B shows a cross-sectional view taken along the dashed-dotted line A1-A2 in FIG. 1A. The cross-sectional view of the subpixels in FIG. 1B can be regarded as being parallel or substantially parallel to the X direction. FIG. 2A shows a cross-sectional view taken along the dashed-dotted line B1-B2 in FIG. 1A. The cross-sectional view of the subpixel in FIG. 2A can be regarded as being parallel or substantially parallel to the Y direction. FIG. 2B and FIG. 2C show cross-sectional views taken along the dashed-dotted line C1-C2 in FIG. 1A.

As illustrated in FIG. 1B and FIG. 2A, in the display apparatus 100, light-emitting devices 130 are provided over a layer 101 including transistors and a protective layer 131 is provided to cover these light-emitting devices. Coloring layers 132R, 132G, and 132B are provided over the protective layer 131, and a substrate 120 is attached to the protective layer 131 with a resin layer 122. In a region between adjacent light-emitting devices, an insulating layer 125 and an insulating layer 127 over the insulating layer 125 are provided.

Although FIG. 1B, FIG. 2A, and the like illustrate a plurality of cross sections of the insulating layer 125 and the insulating layer 127, the insulating layer 125 and the insulating layer 127 are each a continuous layer when the display apparatus 100 is seen from above. In other words, the display apparatus 100 can have a structure including one insulating layer 125 and one insulating layer 127, for example. Note that the display apparatus 100 may include a plurality of insulating layers 125 which are separated from each other and a plurality of insulating layers 127 which are separated from each other.

The display apparatus of one embodiment of the present invention can have any of the following structures: a top-emission structure in which light is emitted in a direction opposite to the substrate where the light-emitting device 130 is formed, a bottom-emission structure where light is emitted toward the substrate where the light-emitting device 130 is formed, and a dual-emission structure where light is emitted toward both surfaces.

The layer 101 including transistors can employ a stacked-layer structure in which a plurality of transistors are provided over a substrate and an insulating layer is provided to cover these transistors, for example. The layer 101 including transistors may have a depressed portion between adjacent light-emitting devices 130. For example, an insulating layer positioned on the outermost surface of the layer 101 including transistors may have a depressed portion. Structure examples of the layer 101 including transistors will be described later in Embodiment 2 and Embodiment 3.

The light-emitting device 130 included in each subpixel includes an EL layer 113 and a common layer 114. Note that the common layer 114 can be regarded as part of the EL layer of the light-emitting device. In this specification and the like, in the EL layers included in the light-emitting devices, an island-shaped layer provided in each light-emitting device is referred to as the EL layer 113, and a layer shared by the plurality of light-emitting devices is referred to as the common layer 114.

The plurality of EL layers 113 are each provided in an island shape. The plurality of EL layers 113 can have the same structure.

For example, the EL layer 113 can contain a light-emitting material emitting blue light and a light-emitting material emitting light with a longer wavelength than blue light. For example, the EL layer 113 can employ a structure containing a light-emitting material emitting blue light and a light-emitting material emitting yellow light, or a structure containing a light-emitting material emitting blue light, a light-emitting material emitting green light, and a light-emitting material emitting red light.

The light-emitting device of this embodiment may have either a single structure (a structure including only one light-emitting unit) or a tandem structure (a structure including two or more light-emitting units). Note that structure examples of the light-emitting device will be described later in Embodiment 4.

The EL layer 113 includes a light-emitting layer. For example, when the light-emitting layer includes a plurality of light-emitting layers whose emission colors are complementary to each other, the light-emitting device 130 can emit white light.

When the light-emitting device 130 configured to emit white light has a microcavity structure described later, light of a specific color such as red, green, or blue is intensified and then emitted in some cases.

As the light-emitting device 130, an OLED (Organic Light Emitting Diode) or a QLED (Quantum-dot Light Emitting Diode) is preferably used, for example. Examples of a light-emitting substance (also referred to as a light-emitting material) contained in the light-emitting device include a substance exhibiting fluorescence (a fluorescent material), a substance exhibiting phosphorescence (a phosphorescent material), and a substance exhibiting thermally activated delayed fluorescence (Thermally activated delayed fluorescence (TADF) material). As the TADF material, a material in which the singlet and triplet excited states are in thermal equilibrium may be used. Since such a TADF material has a short emission lifetime (excitation lifetime), it inhibits a reduction in the efficiency of a light-emitting device in a high-luminance region. An inorganic compound (e.g., a quantum dot material) may also be used as the light-emitting substance contained in the light-emitting device.

The light-emitting device 130 includes an EL layer between a pair of electrodes. The EL layer includes at least a light-emitting layer. In this specification and the like, one of the pair of electrodes may be referred to as a pixel electrode and the other may be referred to as a common electrode.

One of the pair of electrodes of the light-emitting device functions as an anode and the other electrode functions as a cathode. The case where the pixel electrode functions as an anode and the common electrode functions as a cathode is described below as an example in some cases.

The light-emitting device 130 includes a pixel electrode 111 over the layer 101 including transistors, the island-shaped EL layer 113 over the pixel electrode 111, the common layer 114 over the island-shaped EL layer 113, and a common electrode 115 over the common layer 114.

The EL layer 113 includes at least a light-emitting layer. For example, the EL layer 113 may include one or more of a hole-injection layer, a hole-transport layer, a hole-blocking layer, a charge-generation layer, an electron-blocking layer, an electron-transport layer, and an electron-injection layer.

The common layer 114 includes, for example, an electron-injection layer or a hole-injection layer. Alternatively, the common layer 114 may include a stack of an electron-transport layer and an electron-injection layer, and may include a stack of a hole-transport layer and a hole-injection layer. The common layer 114 is shared by the plurality of light-emitting devices 130 and for example, is shared by all of the light-emitting devices 130.

The common electrode 115 is shared by the plurality of light-emitting devices 130 and for example, is shared by all of the light-emitting devices 130. The common electrode 115 shared by the plurality of light-emitting devices 130 is electrically connected to a conductive layer 123 provided in the connection portion 140 (see FIG. 2B and FIG. 2C). The conductive layer 123 is preferably formed using a conductive layer formed using the same material through the same steps as the pixel electrode 111.

Note that FIG. 2B illustrates an example in which the common layer 114 is provided over the conductive layer 123 and the conductive layer 123 and the common electrode 115 are electrically connected to each other through the common layer 114. The common layer 114 is not necessarily provided in the connection portion 140. For example, FIG. 2C illustrates an example where the conductive layer 123 and the common electrode 115 are directly connected to each other. For example, by using a mask for specifying a film formation area (also referred to as an area mask or a rough metal mask), the common layer 114 and the common electrode 115 can be formed in different regions.

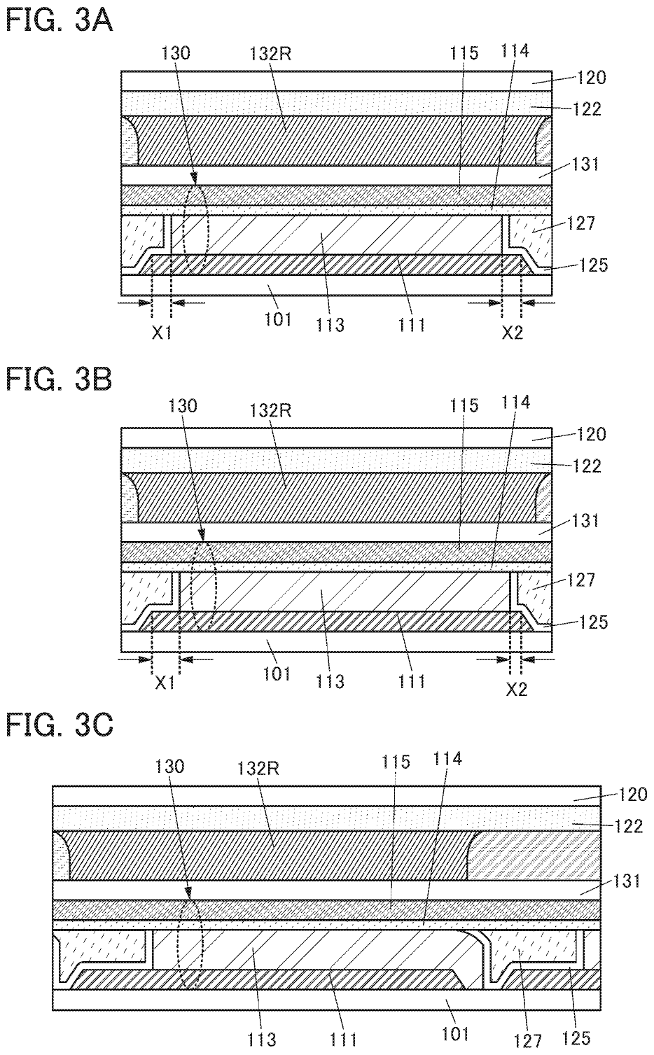

FIG. 3A shows an enlarged view of the light-emitting device illustrated in FIG. 1B and FIG. 2A. In FIG. 3A, the end portion of the EL layer 113 is positioned over the pixel electrode 111.

In FIG. 3A, the EL layer 113 is positioned in the center of the pixel electrode 111. As illustrated in FIG. 3A, in a cross-sectional view, it is preferable that a distance X1 from one end portion of the top surface of the pixel electrode 111 to one end portion of the bottom surface of the EL layer 113 be equal or substantially equal to a distance X2 from the other end portion of the top surface of the pixel electrode 111 to the other end portion of the bottom surface of the EL layer 113.

As illustrated in FIG. 3B, the distance X1 and the distance X2 may be different from each other. FIG. 3B illustrates an example where the EL layer 113 is provided to be close to the right end portion of the pixel electrode 111, and the distance X2 is shorter than the distance X1.

The EL layer 113 may have both an end portion positioned outward from the end portion of the pixel electrode 111 and an end portion positioned inward from the end portion of the pixel electrode 111. In FIG. 3C, the end portion of the EL layer 113 is positioned outward from the end portion of the pixel electrode 111 so as to cover the end portion of the pixel electrode 111. Specifically, FIG. 3C illustrates an example where the left end portion of the EL layer 113 is positioned inward from the left end portion of the pixel electrode 111, and the right end portion of the EL layer 113 covers the right end portion of the pixel electrode 111.

The pixel electrode 111 preferably has an end portion with a tapered shape. When the side surface of the pixel electrode 111 has a tapered shape, coverage with the insulating layer 125 provided along the side surface of the pixel electrode 111 can be improved. Furthermore, when the side surface of the pixel electrode 111 has a tapered shape, a material (also referred to as dust or particles) in the fabrication step is easily removed by processing such as cleaning, which is preferable. Note that in this specification and the like, a tapered shape refers to a shape such that at least part of a side surface of a component is inclined with respect to the substrate surface or the surface where the component is formed. For example, a tapered shape preferably includes a region where the angle formed by the inclined side surface and the substrate surface or the surface where a component is formed (such an angle is also referred to as a taper angle) is less than 90°.

The protective layer 131 is preferably provided over the light-emitting device 130. Providing the protective layer 131 can improve the reliability of the light-emitting device. The protective layer 131 may have a single-layer structure or a stacked-layer structure of two or more layers.

There is no limitation on the conductivity of the protective layer 131. As the protective layer 131, at least one type of an insulating film, a semiconductor film, and a conductive film can be used.

The protective layer 131 including an inorganic film can inhibit deterioration of the light-emitting devices by preventing oxidation of the common electrode 115 and inhibiting entry of impurities (e.g., moisture and oxygen) into the light-emitting device 130, for example; thus, the reliability of the display apparatus can be improved.

As the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, a tantalum oxide film, and the like. Examples of the nitride insulating film include a silicon nitride film, an aluminum nitride film, and the like. Examples of the oxynitride insulating film include a silicon oxynitride film, an aluminum oxynitride film, and the like. Examples of the nitride oxide insulating film include a silicon nitride oxide film, an aluminum nitride oxide film, and the like.

Note that in this specification and the like, oxynitride refers to a material containing more oxygen than nitrogen in its composition, and nitride oxide refers to a material containing more nitrogen than oxygen in its composition. For example, silicon oxynitride refers to a material containing more oxygen than nitrogen in its composition, and silicon nitride oxide refers to a material containing more nitrogen than oxygen in its composition.

The protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can be, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) to the EL layer side.

Furthermore, the protective layer 131 may include an organic film. For example, the protective layer 131 may include both an organic film and an inorganic film.

The protective layer 131 may have a stacked-layer structure of two layers which are formed by different formation methods. Specifically, the first layer of the protective layer 131 may be formed by an ALD method, and the second layer of the protective layer 131 may be formed by a sputtering method.

In the subpixel 110R, the coloring layer 132R transmitting red light is provided over the protective layer 131. Thus, from the subpixel 110R, light emitted by the light-emitting device 130 is extracted as red light to the outside of the display apparatus 100 through the coloring layer 132R. Note that the coloring layer 132R may be shared by a plurality of subpixels 110R adjacent to each other. Furthermore, the coloring layer 132R may be independently provided for each subpixel 110R.

Similarly, in the subpixel 110G, the coloring layer 132G transmitting green light is provided over the protective layer 131. Thus, from the subpixel 110G, light emitted by the light-emitting device 130 is extracted as green light to the outside of the display apparatus 100 through the coloring layer 132G.

In the subpixel 110B, the coloring layer 132B transmitting blue light is provided over the protective layer 131. Thus, from the subpixel 110B, light emitted by the light-emitting device 130 is extracted as blue light to the outside of the display apparatus 100 through the coloring layer 132B.

FIG. 1B and FIG. 2A each illustrate an example in which the coloring layers 132R, 132G, and 132B are directly provided over the light-emitting device 130 with the protective layer 131 therebetween. With such a structure, the alignment accuracy of the light-emitting device 130 and the coloring layer can be improved. It is preferable that the distance between the light-emitting device 130 and the coloring layer be shortened, in which case color mixing can be inhibited and the viewing angle characteristics can be improved.

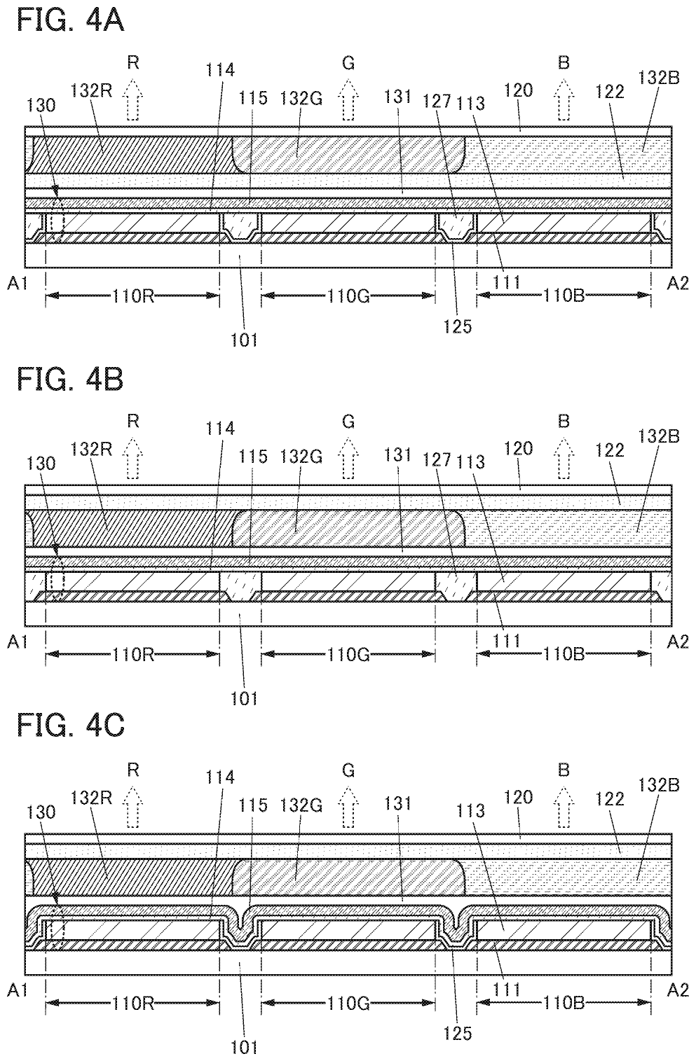

Alternatively, as illustrated in FIG. 4A, the substrate 120 provided with the coloring layers 132R, 132G, and 132B may be attached to the protective layer 131 with the resin layer 122. The coloring layers 132R, 132G, and 132B are provided on the substrate 120, whereby the heat treatment temperature in the forming step of them can be increased.

The side surface of the pixel electrode 111 and the side surface of the EL layer 113 are covered with the insulating layer 125 and the insulating layer 127. Thus, the common layer 114 (or the common electrode 115) can be inhibited from being in contact with the side surface of the pixel electrode 111 and the side surface of the EL layer 113, so that a short circuit of the light-emitting device can be inhibited. Thus, the reliability of the light-emitting device can be improved.

The insulating layer 125 preferably covers at least one of the side surface of the pixel electrode 111 and the side surface of the EL layer 113, and further preferably covers both the side surface of the pixel electrode 111 and the side surface of the EL layer 113. The insulating layer 125 can be in contact with the side surfaces of the pixel electrode 111 and the EL layer 113.

The insulating layer 127 is provided over the insulating layer 125 to fill a depressed portion in the insulating layer 125. The insulating layer 127 can overlap with the side surfaces (or cover the side surfaces) of the pixel electrode 111 and the EL layer 113 with the insulating layer 125 therebetween.

The insulating layer 125 and the insulating layer 127 can fill a space between adjacent island-shaped layers, whereby the formation surface of a layer (e.g., the common electrode) provided over the island-shaped layers can be less uneven and can be flatter. Thus, the coverage with the common electrode can be increased and disconnection of the common electrode can be prevented.

The common layer 114 and the common electrode 115 are provided over the EL layer 113, the insulating layer 125, and the insulating layer 127. At the stage before the insulating layer 125 and the insulating layer 127 are provided, a level difference due to a region where the pixel electrode 111 and the EL layer 113 are provided and a region where the pixel electrode 111 and the EL layer 113 are not provided (a region between the light-emitting devices) is caused. In the display apparatus of one embodiment of the present invention, the level difference can be planarized with the insulating layer 125 and the insulating layer 127, and the coverage with the common layer 114 and the common electrode 115 can be improved. Consequently, it is possible to inhibit a connection defect due to disconnection of the common electrode 115. Alternatively, an increase in electrical resistance due to local thinning of the common electrode 115 caused by level difference can be inhibited.

To improve the planarity of a surface over which the common layer 114 and the common electrode 115 are formed, the levels of the top surface of the insulating layer 125 and the top surface of the insulating layer 127 are aligned or substantially aligned with the level of the top surface of the EL layer 113 at its end portion (also referred to as the level of the end portion of the top surface of the EL layer 113). The top surface of the insulating layer 127 preferably has a flat shape; however, it may include a projecting portion, a convex surface, a concave surface, or a depressed portion.

The insulating layer 125 or the insulating layer 127 can be provided in contact with the island-shaped EL layers 113. Close contact between the insulating layer 125 or the insulating layer 127 and the EL layer 113 has an effect of fixing or bonding adjacent EL layers 113 by the insulating layer 125 or the insulating layer 127. Thus, peeling of the EL layer 113 can be prevented and the reliability of the light-emitting device can be improved. The fabrication yield of the light-emitting device can be increased.

Note that one of the insulating layer 125 and the insulating layer 127 is not necessarily provided. When the insulating layer 125 having a single-layer structure using an inorganic material is formed, for example, the insulating layer 125 can be used as a protective insulating layer for the EL layer 113. In this way, the reliability of the display apparatus can be improved. For another example, when the insulating layer 127 having a single-layer structure using an organic material is formed, the insulating layer 127 can fill a space between adjacent EL layers 113 for planarization. In this way, the coverage with the common electrode 115 (upper electrode) formed over the EL layers 113 and the insulating layer 127 can be increased.

FIG. 4B illustrates an example in which the insulating layer 125 is not provided. In the case where the insulating layer 125 is not provided, the insulating layer 127 can be in contact with the side surfaces of the pixel electrode 111 and the EL layer 113. The insulating layer 127 can be provided to fill spaces between the EL layers 113 of the light-emitting devices 130.

At this time, an organic material that causes less damage to the EL layer 113 is preferably used for the insulating layer 127. For example, for the insulating layer 127, it is preferable to use an organic material such as polyvinyl alcohol (PVA), polyvinyl butyral, polyvinyl pyrrolidone, polyethylene glycol, polyglycerin, pullulan, water-soluble cellulose, or alcohol-soluble polyamide resin.

FIG. 4C illustrates an example in which the insulating layer 127 is not provided.

Note that although FIG. 4C illustrates an example in which the common layer 114 is provided in the depressed portion of the insulating layer 125, spaces may be formed in the regions.

The insulating layer 125 includes a region in contact with the side surface of the EL layer 113 and functions as a protective insulating layer of for EL layer 113. Providing the insulating layer 125 can inhibit entry of impurities (e.g., oxygen and moisture) into the inside of the EL layer 113 through its side surface, resulting in a highly reliable display apparatus.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film, an aluminum nitride film, and the like. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferable because it has high selectivity with respect to the EL layer in etching and has a function of protecting the EL layer in formation of the insulating layer 127 to be described later. An inorganic insulating film such as an aluminum oxide film, a hafnium oxide film, or a silicon oxide film is formed by an ALD method as the insulating layer 125, whereby the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of a barrier insulating layer or a gettering function, entry of impurities (typically, at least one of water and oxygen) that might diffuse into the light-emitting devices from the outside can be inhibited. With this structure, a highly reliable light-emitting device and a highly reliable display apparatus can be provided.

The insulating layer 125 preferably has a low impurity concentration. In this case, deterioration of the EL layer due to entry of impurities from the insulating layer 125 into the EL layer can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 125 can be formed by a sputtering method, a CVD method, a pulsed laser deposition (PLD) method, an ALD method, or the like. The insulating layer 125 is preferably formed by an ALD method achieving good coverage.

When the substrate temperature in forming the insulating layer 125 is increased, the formed insulating layer 125, even with a small thickness, can have a low impurity concentration and a high barrier property against at least one of water and oxygen. Therefore, the substrate temperature is preferably higher than or equal to 60° C., further preferably higher than or equal to 80° C., still further preferably higher than or equal to 100° C., yet still further preferably higher than or equal to 120° C. Meanwhile, the insulating layer 125 is formed after formation of an island-shaped EL layer, the insulating layer 125 is preferably formed at a temperature lower than the upper temperature limit of the EL layer. Therefore, the substrate temperature is preferably lower than or equal to 200° C., further preferably lower than or equal to 180° C., still further preferably lower than or equal to 160° C., still further preferably lower than or equal to 150° C., yet still further preferably lower than or equal to 140° C.

Examples of indicators of the upper temperature limit include the glass transition point, the softening point, the melting point, thermal decomposition temperature, and the 5% weight loss temperature. The upper temperature limit of the EL layer can be, for example, any of the above temperatures, preferably the lowest temperature thereof.

The insulating layer 127 provided over the insulating layer 125 has a function of filling a depressed portion of the insulating layer 125, which is formed between adjacent light-emitting devices. In other words, the insulating layer 127 brings an effect of improving the planarity of a surface where the common electrode 115 is formed. As the insulating layer 127, an insulating layer containing an organic material can be suitably used. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used, for example. Alternatively, an organic material such as polyvinyl alcohol (PVA), polyvinyl butyral, polyvinyl pyrrolidone, polyethylene glycol, polyglycerin, pullulan, water-soluble cellulose, or an alcohol-soluble polyamide resin may be used for the insulating layer 127. Alternatively, a photosensitive resin can be used for the insulating layer 127. A photoresist may be used for the photosensitive resin. As the photosensitive resin, a positive photosensitive material or a negative photosensitive material can be used.

The insulating layer 127 may be formed using a material absorbing visible light. When the insulating layer 127 absorbs light emitted from the light-emitting device, leakage of light (stray light) from the light-emitting device to the adjacent light-emitting device through the insulating layer 127 can be inhibited. Thus, the display quality of the display apparatus can be improved. Since the display quality of the display apparatus can be improved without using a polarizing plate, the weight and thickness of the display apparatus can be reduced.

Examples of the material absorbing visible light include a material containing a pigment of black or the like, a material containing a dye, a light-absorbing resin material (e.g., polyimide), and a resin material that can be used for color filters (a color filter material). Using a resin material obtained by stacking or mixing color filter materials of two colors or three or more colors is particularly preferred to enhance the effect of blocking visible light. In particular, mixing color filter materials of three or more colors enables the formation of a black or nearly black resin layer.

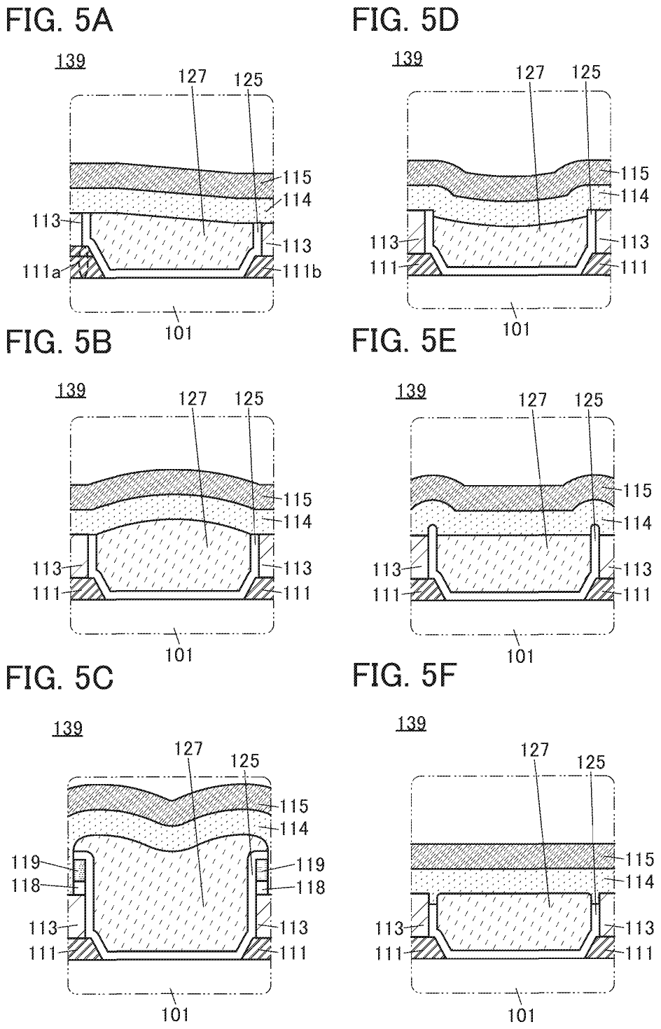

FIG. 5A to FIG. 5F each illustrate a cross-sectional structure of a region 139 including the insulating layer 127 and its surroundings.

FIG. 5A illustrates an example in which the thickness of the pixel electrode differs between subpixels of different colors. Specifically, the thickness of a pixel electrode 111a and the thickness of a pixel electrode 111b are different from each other. FIG. 5A illustrates an example where the pixel electrode 111a has a two-layer structure and the pixel electrode 111b has a single-layer structure. In FIG. 5A, there is no limitation on the number of stacked layers in each of the pixel electrodes 111a and 111b as long as the pixel electrodes 111a and 111b have different thicknesses. Since the EL layer 113 is formed in common between the subpixels of different colors, the thickness of the EL layer 113 over the pixel electrode 111a and the thickness of the EL layer 113 over the pixel electrode 111b are the same or substantially the same. Therefore, the top surface level of the EL layer 113 over the pixel electrode 111a is different from that over the pixel electrode 111b. On both the pixel electrode 111a side and the pixel electrode 111b side, the top surface of the insulating layer 125 is at the same level or substantially the same level as that of the EL layer 113. The top surface of the insulating layer 127 has a gentle slope such that the side closer to the pixel electrode 111a is higher and the side closer to the pixel electrode 111b is lower. In this manner, the levels of the insulating layer 125 and the insulating layer 127 are preferably equal to the top surface levels of the adjacent EL layers. Alternatively, the insulating layer 127 may have a flat portion that is level with the top surface of any adjacent EL layer.

In FIG. 5B, the top surface of the insulating layer 127 has a region that is at a higher level than the top surface of the EL layer 113. As illustrated in FIG. 5B, the top surface of the insulating layer 127 can have, in a cross-sectional view, a shape in which the center and its vicinity are bulged, i.e., a shape including a convex surface.

In the cross-sectional view of FIG. 5C, the top surface of the insulating layer 127 has a shape that is gently bulged toward the center, i.e., has a convex surface, and has a shape that is recessed in the center and its vicinity, i.e., has a concave surface. The insulating layer 127 has a region that is at a higher level than the top surface of the EL layer 113. In the region 139, the display apparatus includes at least one of a sacrificial layer 118 and a sacrificial layer 119. The end portion of the insulating layer 125 and the end portion of the insulating layer 127 overlap with the top surface of the EL layer 113 and are positioned over at least one of the sacrificial layer 118 and the sacrificial layer 119.

In FIG. 5D, the top surface of the insulating layer 127 includes a region that is at a lower level than the top surface of the EL layer 113. In the cross-sectional view, the top surface of the insulating layer 127 has a shape that is recessed in the center and its vicinity, i.e., has a concave surface.

In FIG. 5E, the top surface of the insulating layer 125 includes a region that is at a higher level than the top surface of the EL layer 113. That is, the insulating layer 125 protrudes from the formation surface of the common layer 114 and forms a projecting portion.

In formation of the insulating layer 125, for example, when the insulating layer 125 is formed to be level or substantially level with the sacrificial layer, the insulating layer 125 may protrude as illustrated in FIG. 5E.

In FIG. 5F, the top surface of the insulating layer 125 includes a region that is at a lower level than the top surface of the EL layer 113. That is, the insulating layer 125 forms a depressed portion on the formation surface of the common layer 114.

As described above, the insulating layer 125 and the insulating layer 127 can have a variety of shapes.

As the sacrificial layer, one or more kinds of inorganic films such as a metal film, an alloy film, a metal oxide film, a semiconductor film, and an inorganic insulating film can be used, for example.

For example, a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials can be used for the sacrificial layer.

For the sacrificial layer, a metal oxide such as In—Ga—Zn oxide can be used. As the sacrificial layer, an In—Ga—Zn oxide film can be formed by a sputtering method, for example. Furthermore, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like can be used. Indium tin oxide containing silicon, or the like can also be used.

In addition, in place of gallium described above, an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

As the sacrificial layer, a variety of inorganic insulating films that can be used as the protective layer 131 can be used. In particular, an oxide insulating film is preferable because its adhesion to the EL layer is higher than that of a nitride insulating film. For example, an inorganic insulating material such as aluminum oxide, hafnium oxide, or silicon oxide can be used for the sacrificial layer. As the sacrificial layer, an aluminum oxide film can be formed by an ALD method, for example. The use of an ALD method is preferable, in which case damage to a base (in particular, the EL layer or the like) can be reduced. For example, a silicon nitride film can be formed by a sputtering method.

For example, the sacrificial layer can employ a stacked-layer structure of an inorganic insulating film (e.g., an aluminum oxide film) formed by an ALD method and an In—Ga—Zn oxide film formed by a sputtering method. Alternatively, the sacrificial layer can employ a stacked-layer structure of an inorganic insulating film (e.g., an aluminum oxide film) formed by an ALD method and an aluminum film, a tungsten film, or an inorganic insulating film (e.g., a silicon nitride film) formed by a sputtering method.

In the display apparatus of this embodiment, the distance between light-emitting devices can be shortened. Specifically, the distance between the light-emitting devices, the distance between the EL layers, or the distance between the pixel electrodes can be less than 10 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where a distance between two EL layers 113 adjacent to each other is less than or equal to 1 μm, preferably less than or equal to 0.5 μm (500 nm), further preferably less than or equal to 100 nm.

A light-blocking layer may be provided on the surface of the substrate 120 on the resin layer 122 side. For the light-blocking layer, a material that blocks light emitted by the light-emitting device can be used. The light-blocking layer preferably absorbs visible light. As the light-blocking layer, a black matrix can be formed using a metal material or a resin material containing pigment (e.g., carbon black) or dye, for example. The light-blocking layer may have a stacked-layer structure of at least two layers of a red color filter, a green color filter, and a blue color filter.

Moreover, a variety of optical members can be provided on the outer surface of the substrate 120. Examples of optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, it is preferable to provide, as the surface protective layer, a glass layer or a silica layer (SiOₓ layer) because the surface contamination or damage can be inhibited from being generated. The surface protective layer may be formed using DLC (diamond like carbon), aluminum oxide (AlOₓ), a polyester-based material, a polycarbonate-based material, or the like. For the surface protective layer, a material having a high visible-light-transmitting property is preferably used. The surface protective layer is preferably formed using a material with high hardness.

For the substrate 120, glass, quartz, ceramic, sapphire, a resin, a metal, an alloy, a semiconductor, or the like can be used. The substrate on the side from which light from the light-emitting device is extracted is formed using a material transmitting the light. When a flexible material is used for the substrate 120, the display apparatus can have increased flexibility and a flexible display can be achieved. Furthermore, a polarizing plate may be used as the substrate 120.

For the substrate 120, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of films having high optical isotropy include a triacetyl cellulose (TAC, also referred to as cellulose triacetate) film, a cycloolefin polymer (COP) film, a cycloolefin copolymer (COC) film, and an acrylic film.

When a film used as the substrate absorbs water, the shape of the display panel might be changed, e.g., creases might be caused. Thus, as the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-component-mixture-type resin may be used. An adhesive sheet or the like may be used.

Next, materials that can be used for the light-emitting device will be described.

A conductive film transmitting visible light is used as the electrode through which light is extracted, which is either the pixel electrode or the common electrode. A conductive film reflecting visible light is preferably used as the electrode through which light is not extracted. In the case where a display apparatus includes a light-emitting device emitting infrared light, a conductive film transmitting visible light and infrared light is used as the electrode through which light is extracted, and a conductive film reflecting visible light and infrared light is preferably used as the electrode through which light is not extracted.

A conductive film transmitting visible light may be used also as an electrode through which light is not extracted. In this case, this electrode is preferably placed between a reflective layer and the EL layer. In other words, light emitted by the EL layer may be reflected by the reflective layer to be extracted from the display apparatus.

As a material that forms the pair of electrodes (the pixel electrode and the common electrode) of the light-emitting device, a metal, an alloy, an electrically conductive compound, a mixture thereof, and the like can be used as appropriate. Specific examples include indium tin oxide (In—Sn oxide, also referred to as ITO), In—Si—Sn oxide (also referred to as ITSO), indium zinc oxide (In—Zn oxide), In—W—Zn oxide, an alloy containing aluminum (an aluminum alloy) such as an alloy of aluminum, nickel, and lanthanum (Al—Ni—La), and an alloy of silver, palladium, and copper (Ag—Pd—Cu, also referred to as APC). In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The light-emitting devices preferably employ a microcavity structure. Therefore, one of the pair of electrodes of the light-emitting device is preferably an electrode having properties of transmitting and reflecting visible light (a semi-transmissive and semi-reflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified.

The semi-transmissive and semi-reflective electrode can have a stacked-layer structure of a reflective electrode and an electrode having a visible-light-transmitting property (also referred to as a transparent electrode).

The transparent electrode has a light transmittance higher than or equal to 40%. For example, an electrode having a visible light (light at wavelengths greater than or equal to 400 nm and less than 750 nm) transmittance higher than or equal to 40% is preferably used in the light-emitting device. The visible light reflectance of the semi-transmissive and semi-reflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity of 1×10⁻² Ωcm or lower.

The EL layer is a layer containing a light-emitting material. The light-emitting layer can contain one or more kinds of light-emitting materials. As the light-emitting material, a substance whose emission color is blue, violet, bluish violet, green, yellowish green, yellow, orange, red, or the like is appropriately used. Alternatively, as the light-emitting material, a substance emitting near-infrared light can be used.

Examples of the light-emitting material include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting material (a guest material). As one or more kinds of organic compounds, one or both of a hole-transport material and an electron-transport material can be used. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting material (phosphorescent material). When a combination of materials is selected so as to form an exciplex that exhibits light emission whose wavelength overlaps with the wavelength on a lowest-energy-side absorption band of the light-emitting material, energy can be transferred smoothly and light emission can be obtained efficiently. With the above structure, high efficiency, low-voltage driving, and a long lifetime of a light-emitting device can be achieved at the same time.

In addition to the light-emitting layer, the EL layer 113 may further include a layer containing any of a substance with a high hole-injection property, a substance with a high hole-transport property (also referred to as a hole-transport material), a hole-blocking material, a substance with a high electron-transport property (also referred to as an electron-transport material), a substance with a high electron-injection property, an electron-blocking material, a substance with a bipolar property (also referred to as a substance with a high electron-transport property and a high hole-transport property or a bipolar material), and the like.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

For example, the EL layer 113 may include one or more of a hole-injection layer, a hole-transport layer, a hole-blocking layer, an electron-blocking layer, an electron-transport layer, and an electron-injection layer.

As the common layer 114, one or more of a hole-injection layer, a hole-transport layer, a hole-blocking layer, an electron-blocking layer, an electron-transport layer, and an electron-injection layer can be used. For example, a carrier-injection layer (a hole-injection layer or an electron-injection layer) may be formed as the common layer 114. Note that the light-emitting device 130 does not necessarily include the common layer 114.

The EL layer 113 preferably includes a light-emitting layer and a carrier-transport layer over the light-emitting layer. Accordingly, the light-emitting layer is inhibited from being exposed on the outermost surface in the fabrication process of the display apparatus 100, so that damage to the light-emitting layer can be reduced. Thus, the reliability of the light-emitting device can be improved.

A hole-injection layer is a layer injecting holes from an anode to a hole-transport layer, and a layer containing a material with a high hole-injection property. Examples of a substance with a high hole-injection property include an aromatic amine compound and a composite material containing a hole-transport material and an acceptor material (electron-accepting material).

A hole-transport layer is a layer transporting holes, which are injected from an anode by a hole-injection layer, to a light-emitting layer. The hole-transport layer is a layer containing a hole-transport material. As the hole-transport material, a substance with a hole mobility higher than or equal to 1×10⁻⁶ cm²/Vs is preferred. Note that other substances can also be used as long as the substances have a hole-transport property higher than an electron-transport property. As the hole-transport material, a substance with a high hole-transport property, such as a T-electron rich heteroaromatic compound (e.g., a carbazole derivative, a thiophene derivative, or a furan derivative) or an aromatic amine (a compound having an aromatic amine skeleton), is preferred.

An electron-transport layer is a layer transporting electrons, which are injected from a cathode by an electron-injection layer, to a light-emitting layer. The electron-transport layer is a layer containing an electron-transport material. As the electron-transport material, a substance with an electron mobility higher than or equal to 1×10⁻⁶ cm²/Vs is preferred. Note that other substances can also be used as long as the substances have an electron-transport property higher than a hole-transport property. As the electron-transport material, any of the following substances with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The electron-injection layer is a layer injecting electrons from a cathode to an electron-transport layer and is a layer containing a substance with a high electron-injection property. As the substance with a high electron-injection property, an alkali metal, an alkaline earth metal, or a compound thereof can be used. As the substance with a high electron-injection property, a composite material containing an electron-transport material and a donor material (electron-donating material) can also be used.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOx), or cesium carbonate, for example. The electron-injection layer may have a stacked-layer structure of two or more layers. In the stacked-layer structure, for example, lithium fluoride can be used for the first layer and ytterbium can be used for the second layer.

Alternatively, the electron-injection layer may be formed using an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition temperature (Tg) than BPhen and thus has high heat resistance.

In the case where the light-emitting device 130 has a tandem structure, a charge-generation layer is preferably provided between two light-emitting units. The charge-generation layer includes at least a charge-generation region. The charge-generation layer has a function of injecting electrons into one of the two light-emitting units and injecting holes into the other when voltage is applied between the pair of electrodes.

As described above, the charge-generation layer includes at least a charge-generation region. The charge-generation region preferably contains an acceptor material, and for example, preferably contains a hole-transport material and an acceptor material which can be used for the hole-injection layer.

The charge-generation layer preferably includes a layer containing a substance with a high electron-injection property. The layer can also be referred to as an electron-injection buffer layer. The electron-injection buffer layer is preferably provided between the charge-generation region and the electron-transport layer. By provision of the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can include an alkali metal compound or an alkaline earth metal compound. Specifically, the electron-injection buffer layer preferably includes an inorganic compound containing an alkali metal and oxygen or an inorganic compound containing an alkaline earth metal and oxygen, further preferably includes an inorganic compound containing lithium and oxygen (e.g., lithium oxide (LizO)). Alternatively, a material that can be used for the electron-injection layer can be suitably used for the electron-injection buffer layer.

The charge-generation layer preferably includes a layer containing a substance with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper(II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer sometimes cannot be clearly distinguished from each other on the basis of the cross-sectional shapes, the characteristics, or the like.

Note that the charge-generation layer may contain a donor material instead of an acceptor material. For example, the charge-generation layer may include a layer containing an electron-transport material and a donor material, which can be used for the electron-injection layer.

When the light-emitting units are stacked, provision of a charge-generation layer between two light-emitting units can suppress an increase in driving voltage.

### Fabrication Method Example of Display Apparatus

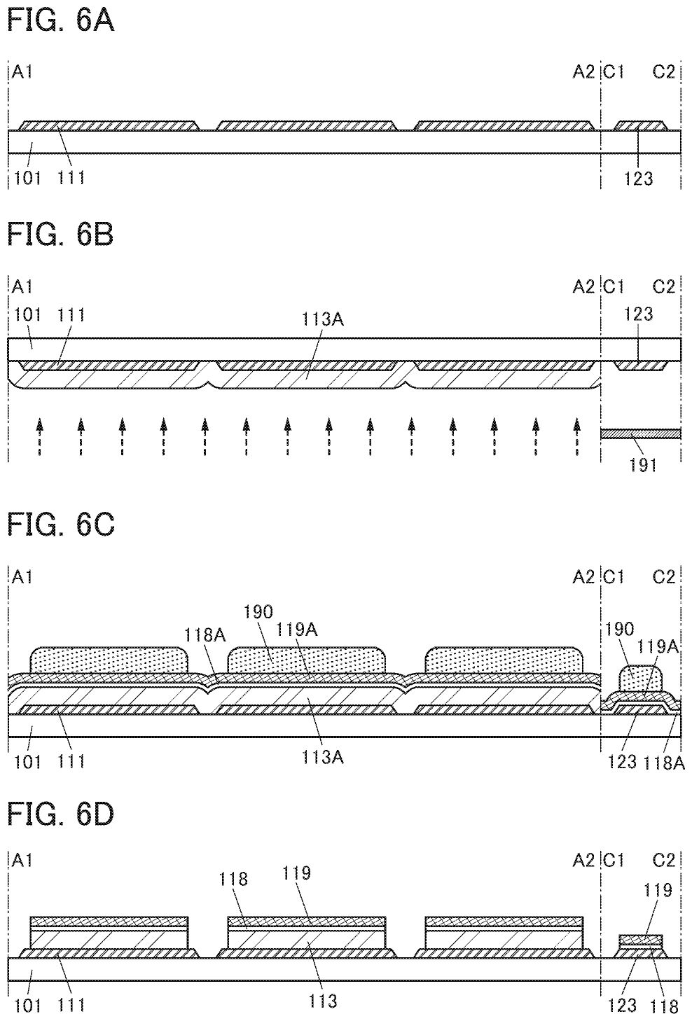

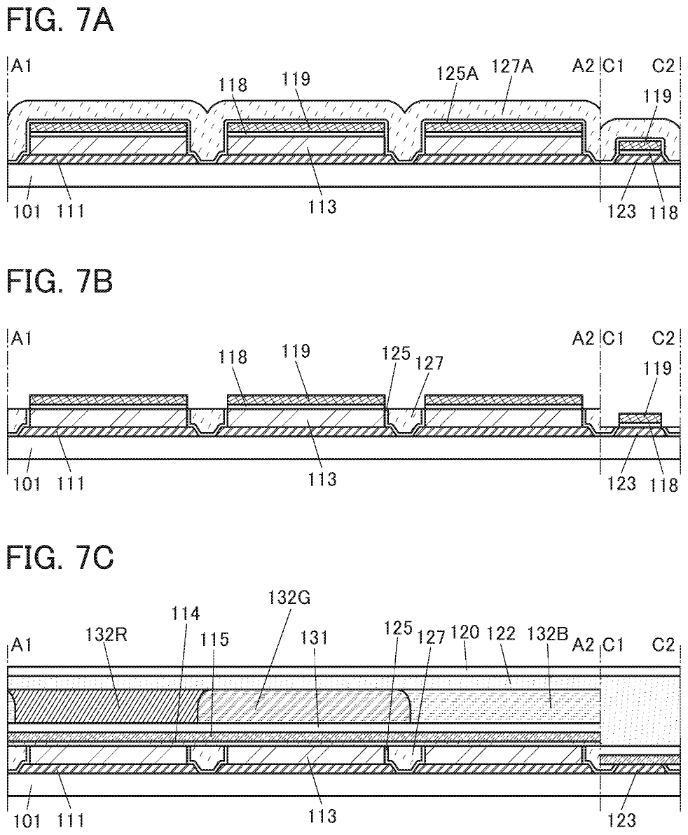

Next, an example of a method for fabricating a display apparatus is described with reference to FIG. 6 and FIG. 7. FIG. 6A to FIG. 6D and FIG. 7A to FIG. 7C each show a cross-sectional view along the dashed-dotted line A1-A2 and a cross-sectional view along the dashed-dotted line C1-C2 in FIG. 1A side by side.

Thin films included in the display apparatus (e.g., insulating films, semiconductor films, and conductive films) can be formed by a sputtering method, a CVD method, a vacuum evaporation method, a PLD method, an ALD method, or the like. Examples of a CVD method include a PECVD method and a thermal CVD method. An example of a thermal CVD method is a metal organic chemical vapor deposition (MOCVD: Metal Organic CVD) method.

Alternatively, the thin films included in the display apparatus (insulating films, semiconductor films, conductive films, and the like) can be formed by a method such as spin coating, dipping, spray coating, ink-jetting, dispensing, screen printing, offset printing, doctor blade coating, slit coating, roll coating, curtain coating, or knife coating.

Specifically, for fabrication of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a light-emitting layer, an electron-transport layer, and an electron-injection layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an inkjet method, a screen printing (stencil) method, an offset printing (planography) method, a flexography (relief printing) method, a gravure printing method, or a micro-contact printing method), or the like.

Thin films included in the display apparatus can be processed by a photolithography method or the like. Alternatively, thin films may be processed by a nanoimprinting method, a sandblasting method, a lift-off method, or the like. Alternatively, island-shaped thin films may be directly formed by a film formation method using a shielding mask such as a metal mask.

There are two typical methods in a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used. It is preferable to use extreme ultraviolet light, X-rays, or an electron beam because extremely minute processing can be performed. Note that a photomask is not needed when exposure is performed by scanning with a beam such as an electron beam.

For etching of thin films, a dry etching method, a wet etching method, a sandblast method, or the like can be used.

First, the pixel electrode 111 and the conductive layer 123 are formed over the layer 101 including transistors (FIG. 6A). The pixel electrode 111 can be formed by a sputtering method or a vacuum evaporation method, for example.

Next, an EL film 113A that is to be the EL layer 113 later is formed over the pixel electrode 111 and the layer 101 including transistors (FIG. 6B).

As illustrated in FIG. 6B, the EL film 113A is not formed over the conductive layer 123 in the cross-sectional view along the dashed-dotted line C1-C2. For example, a mask 191 for specifying a film formation area (also referred to as an area mask or a rough metal mask to be distinguished from a fine metal mask) is used, so that the EL film 113A can be formed only in a desired region. In one embodiment of the present invention, the light-emitting device is formed using a resist mask; by using a combination of a resist mask and an area mask as described above, the light-emitting device can be fabricated through a relatively simple process.

The EL film 113A can be formed by an evaporation method, specifically a vacuum evaporation method, for example. FIG. 6B illustrates a state where film formation is performed under a condition that the substrate is inverted so that a film formation surface faces downward, i.e., film formation is performed with a face-down system.

Alternatively, the EL film 113A may be formed by a transfer method, a printing method, an inkjet method, a coating method, or the like.

Next, over the EL film 113A and the conductive layer 123, a sacrificial film 118A that is to be the sacrificial layer 118 and a sacrificial film 119A that is to be the sacrificial layer 119 are sequentially formed (FIG. 6C). As the sacrificial film 118A and the sacrificial film 119A, a film that is highly resistant to the processing conditions for the EL film 113A, specifically, a film having high etching selectivity with EL film 113A is used.

The sacrificial film 118A and the sacrificial film 119A can be formed by a sputtering method, an ALD method (including a thermal ALD method or a PEALD method), a CVD method, or a vacuum evaporation method, for example. Note that the sacrificial film 118A, which is formed over and in contact with the EL film 113A, is preferably formed by a formation method that causes less damage to the EL film 113A than a formation method for the sacrificial film 119A. For example, the sacrificial film 118A is preferably formed by an ALD method or a vacuum evaporation method rather than a sputtering method. The sacrificial film 118A and the sacrificial film 119A are formed at a temperature lower than the upper temperature limit of the EL film 113A. The typical substrate temperatures in formation of the sacrificial film 118A and the sacrificial film 119A are each lower than or equal to 200° C., preferably lower than or equal to 150° C., further preferably lower than or equal to 120° C., still further preferably lower than or equal to 100° C., yet still further preferably lower than or equal to 80° C.

As the sacrificial film 118A and the sacrificial film 119A, it is preferable to use a film that can be removed by a wet etching method. Using a wet etching method can reduce damage to the EL film 113A in processing the sacrificial film 118A and the sacrificial film 119A, as compared to the case of using a dry etching method.

As the sacrificial film 118A, it is preferable to use a film having high etching selectivity with the sacrificial film 119A.

In the method for fabricating a display apparatus of this embodiment, it is desirable that the layers (e.g., the hole-injection layer, the hole-transport layer, the light-emitting layer, and the electron-transport layer) included in the EL film not be easily processed in the step of processing the sacrificial films, and that the sacrificial films not be easily processed in the steps of processing the layers included in the EL film. The materials and the processing method for the sacrificial films and the processing method for the EL film are preferably selected in consideration of the above.

Although this embodiment describes an example in which the sacrificial film is formed with a two-layer structure of the sacrificial film 118A and the sacrificial film 119A, the sacrificial film may have a single-layer structure or a stacked-layer structure of three or more layers.

As the sacrificial film 118A and the sacrificial film 119A, it is possible to use an organic insulating film or an inorganic film such as a metal film, an alloy film, a metal oxide film, a semiconductor film, or an inorganic insulating film, for example.

For the sacrificial film 118A and the sacrificial film 119A, it is preferable to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. The use of a metal material capable of blocking ultraviolet light for one or both of the sacrificial film 118A and the sacrificial film 119A is preferable, in which case the EL film can be inhibited from being irradiated with ultraviolet light and deteriorating.

For the sacrificial film 118A and the sacrificial film 119A, a metal oxide such as In—Ga—Zn oxide can be used. As the sacrificial film 118A or the sacrificial film 119A, an In—Ga—Zn oxide film can be formed by a sputtering method, for example. Furthermore, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like can be used. Indium tin oxide containing silicon, or the like can also be used.

In addition, in place of gallium described above, the element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like) may be used.

As the sacrificial film 118A and the sacrificial film 119A, a variety of inorganic insulating films that can be used as the protective layer 131 can be used. In particular, an oxide insulating film is preferable because its adhesion to the EL layer is higher than that of a nitride insulating film. For example, an inorganic insulating material such as aluminum oxide, hafnium oxide, or silicon oxide can be used for the sacrificial film 118A and the sacrificial film 119A. As the sacrificial film 118A or the sacrificial film 119A, an aluminum oxide film can be formed by an ALD method, for example. The use of an ALD method is preferable, in which case damage to a base (in particular, the EL layer or the like) can be reduced.

For example, an inorganic insulating film (e.g., an aluminum oxide film) formed by an ALD method can be used as the sacrificial film 118A, and an inorganic film (e.g., an In—Ga—Zn oxide film, an aluminum film, or a tungsten film) formed by a sputtering method can be used as the sacrificial film 119A.

Note that the same inorganic insulating film can be used for both the sacrificial film 118A and the insulating layer 125 that is to be formed later. For example, an aluminum oxide film formed by an ALD method can be used for both the sacrificial film 118A and the insulating layer 125. Here, for the sacrificial film 118A and the insulating layer 125, the same film-formation condition may be used or different film-formation conditions may be used. For example, when the sacrificial film 118A is formed under conditions similar to those of the insulating layer 125, the sacrificial film 118A can be an insulating layer having a high barrier property against at least one of water and oxygen. Meanwhile, the sacrificial film 118A is a layer almost or all of which is to be removed in a later step, and thus is preferably easy to process. Therefore, the sacrificial film 118A is preferably formed with a substrate temperature lower than that for formation of the insulating layer 125.

An organic material may be used for one or both of the sacrificial film 118A and the sacrificial film 119A. For example, as the organic material, a material that can be dissolved in a solvent chemically stable with respect to at least a film positioned in the uppermost portion of the EL film 113A may be used. Specifically, a material that will be dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed in a reduced-pressure atmosphere, in which case the solvent can be removed at a low temperature in a short time and thermal damage to the EL layer can be reduced accordingly.

The sacrificial film 118A and the sacrificial film 119A may be formed by a wet film formation method such as spin coating, dipping, spray coating, ink-jetting, dispensing, screen printing, offset printing, doctor knife coating, slit coating, roll coating, curtain coating, or knife coating.

The sacrificial film 118A and the sacrificial film 119A may each be formed using an organic resin such as polyvinyl alcohol (PVA), polyvinyl butyral, polyvinylpyrrolidone, polyethylene glycol, polyglycerin, pullulan, water-soluble cellulose, or an alcohol-soluble polyamide resin. The sacrificial film 118A and the sacrificial film 119A may each be formed using a fluorine resin such as a perfluoro polymer.

For example, an organic film (e.g., a PVA film) formed by an evaporation method or the above wet film formation method can be used as the sacrificial film 118A, and an inorganic film (e.g., a silicon nitride film) formed by a sputtering method can be used as the sacrificial film 119A.

Next, a resist mask 190 is formed over the sacrificial film 119A (FIG. 6C). The resist mask 190 can be formed by application of a photosensitive resin (photoresist), exposure, and development.

The resist mask may be formed using either a positive resist material or a negative resist material.

The resist mask 190 is provided at a position overlapping with the pixel electrode 111. As the resist mask 190, one island-shaped pattern is preferably provided for one subpixel.

Note that the resist mask 190 is preferably provided also at a position overlapping with the conductive layer 123. This can inhibit the conductive layer 123 from being damaged during the fabrication process of the display apparatus. Note that the resist mask 190 is not necessarily provided over the conductive layer 123.

Next, part of the sacrificial film 119A is removed using the resist mask 190, so that the sacrificial layer 119 is formed (FIG. 6D). The sacrificial layer 119 partly remains over the pixel electrode 111 and the conductive layer 123.

In the etching of the sacrificial film 119A, an etching condition with high selectivity is preferably employed so that the sacrificial film 118A is not removed by the etching. Since the EL film 113A is not exposed in processing the sacrificial film 119A, the range of choices of the processing method is wider than that for processing the sacrificial film 118A. Specifically, deterioration of the EL film 113A can be further inhibited even when a gas containing oxygen is used as an etching gas in processing the sacrificial film 119A.

After that, the resist mask 190 is removed. The resist mask 190 can be removed by ashing using oxygen plasma, for example. Alternatively, an oxygen gas and any of CF₄, C₄F₈, SF₆, CHF₃, Cl₂, H₂O, BCl₃, or a noble gas (also referred to as a rare gas) such as He may be used. Alternatively, the resist mask 190 may be removed by wet etching. At this time, the sacrificial film 118A is positioned on the outermost surface and the EL film 113A is not exposed; thus, the EL film 113A can be inhibited from being damaged in the step of removing the resist mask 190. In addition, the range of choices of the method for removing the resist mask 190 can be widened.

Next, part of the sacrificial film 118A is removed using the sacrificial layer 119 as a mask (also referred to as hard mask) to form the sacrificial layer 118 (FIG. 6D).

The sacrificial film 118A and the sacrificial film 119A can be processed by a wet etching method or a dry etching method. The sacrificial film 118A and the sacrificial film 119A are preferably processed by anisotropic etching.

Using a wet etching method can reduce damage to the EL film 113A in processing the sacrificial film 118A and the sacrificial film 119A, as compared to the case of using a dry etching method. In the case of using a wet etching method, it is preferable to use a developer, a tetramethylammonium hydroxide (TMAH) aqueous solution, dilute hydrofluoric acid, oxalic acid, phosphoric acid, acetic acid, nitric acid, or a chemical solution containing a mixed solution of any of these acids, for example.

In the case of using a dry etching method, deterioration of the EL film 113A can be inhibited by not using a gas containing oxygen as the etching gas. In the case of using a dry etching method, it is preferable to use a gas containing CF₄, C₄F₈, SF₆, CHF₃, Cl₂, H₂O, or BCl₃ or a noble gas (also referred to as a rare gas) such as He as the etching gas, for example.

For example, when an aluminum oxide film formed by an ALD method is used as the sacrificial film 118A, the sacrificial film 118A can be processed by a dry etching method using CHF₃ and He. In the case where an In—Ga—Zn oxide film formed by a sputtering method is used as the sacrificial film 119A, the sacrificial film 119A can be processed by a wet etching method using a diluted phosphoric acid. Alternatively, the sacrificial film 119A may be processed by a dry etching method using CH₄ and Ar. Alternatively, the sacrificial film 119A can be processed by a wet etching method using a diluted phosphoric acid. When a tungsten film formed by a sputtering method is used as the sacrificial film 119A, the sacrificial film 119A can be processed by a dry etching method using a combination of SF₆, CF₄, and O₂ or a combination of CF₄, Cl₂, and O₂.

Next, the EL film 113A is processed to form the EL layer 113. For example, part of the EL film 113A is removed using the sacrificial layer 119 and the sacrificial layer 118 as a hard mask to form the EL layer 113 (FIG. 6D).

The EL film 113A is processed as illustrated in FIG. 6D, whereby a plurality of EL layers 113 can be formed. That is, the EL film 113A can be divided into a plurality of EL layers 113. Note that the EL film 113A is not necessarily divided in either the row direction or the column direction. In this case, the EL layer 113 can have a belt-like shape.

The EL film 113A is preferably processed by anisotropic etching. In particular, an anisotropic dry etching is preferably used. Alternatively, a wet etching may be used.

In the case of using a dry etching method, deterioration of the EL film 113A can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Thus, damage to the EL film 113A can be inhibited. Furthermore, a defect such as attachment of a reaction product generated at the etching can be inhibited.

In the case of using a dry etching method, it is preferable to use a gas containing at least one of H₂, CF₄, C₄F₈, SF₆, CHF₃, Cl₂, H₂O, BCl₃, and a noble gas (also referred to as a rare gas) such as He and Ar as the etching gas, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. As another example, a gas containing CF₄, He, and oxygen can be used as the etching gas.

As described above, in one embodiment of the present invention, the sacrificial layer 119 is formed in the following manner: the resist mask 190 is formed over the sacrificial film 119A, and part of the sacrificial film 119A is removed using the resist mask 190. After that, part of the EL film 113A is removed using the sacrificial layer 119 as a hard mask, so that the EL layer 113 is formed. In other words, the EL layer 113 can be formed by processing the EL film 113A by a photolithography method. Note that part of the EL film 113A may be removed using the resist mask 190. Then, the resist mask 190 may be removed.

Each subpixel includes the island-shaped EL layer 113, which can inhibit generation of leakage current between the subpixels. Accordingly, degradation of the display quality of the display apparatus can be inhibited. In addition, both the higher resolution and higher display quality of the display apparatus can be achieved.

Next, an insulating film 125A that is to be the insulating layer 125 later is formed over the pixel electrode 111, the EL layer 113, the sacrificial layer 118, and the sacrificial layer 119 (FIG. 7A).

The insulating film 125A can be formed using the above-described material that can be used for the insulating layer 125.

As the insulating film 125A, an insulating film is preferably formed at a substrate temperature higher than or equal to 60° C., higher than or equal to 80° C., higher than or equal to 100° C., or higher than or equal to 120° C. and lower than or equal to 200° ° C., lower than or equal to 180° C., lower than or equal to 160° C., lower than or equal to 150° C., or lower than or equal to 140° C. to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm, for example.

As the insulating film 125A, an aluminum oxide film is preferably formed by an ALD method, for example.

Then, an insulating film 127A is formed over the insulating film 125A (FIG. 7A).

The insulating film 127A can be formed using any of the above-described materials that can be used for the insulating layer 127.

A photosensitive material, for example, a photosensitive resin, can be used for the insulating film 127A. For example, the insulating film 127A can be formed by a wet film formation method such as spin coating, dipping, spray coating, ink-jetting, dispensing, screen printing, offset printing, doctor knife coating, slit coating, roll coating, curtain coating, or knife coating. Specifically, an organic insulating film that is to be the insulating film 127 is preferably formed by spin coating.

The insulating film 125A and the insulating film 127A are preferably formed by a formation method that causes less damage to the EL layer 113. In particular, the insulating film 125A, which is formed in contact with the side surface of the EL layer 113, is preferably formed by a formation method that causes less damage to the EL layer 113 than the formation method of the insulating film 127A. In addition, the insulating film 125A and the insulating film 127A are each formed at a temperature lower than the upper temperature limit of the EL layer 113. The typical substrate temperatures in formation of the insulating film 125A and the insulating film 127A are each lower than or equal to 200° C., preferably lower than or equal to 180° C., further preferably lower than or equal to 160° C., still further preferably lower than or equal to 150° C., yet still further preferably lower than or equal to 140° C. As the insulating film 125A, an aluminum oxide film can be formed by an ALD method, for example. The use of an ALD method is preferable, in which case damage by the film formation is reduced and a film with good coverage can be formed.

Next, the insulating film 127A is processed to form the insulating layer 127 (FIG. 7B). For example, in the case where a photosensitive material is used for the insulating film 127A, exposure and development are performed on the insulating film 127A, whereby the insulating layer 127 can be formed. Etching may be performed so that the surface level of the insulating layer 127 is adjusted. The insulating layer 127 may be processed by ashing using oxygen plasma, for example. In the case where a non-photosensitive material is used for the insulating film 127A, the surface level of the insulating layer 127 can be adjusted by the ashing, for example.

Next, at least part of the insulating film 125A is removed to form the insulating layer 125 (FIG. 7B).

The insulating film 125A is preferably processed by a dry etching method. The insulating film 125A is preferably processed by anisotropic etching. The insulating film 125A can be processed using an etching gas that can be used for processing the sacrificial film.

After that, the sacrificial layer 119 and the sacrificial layer 118 are removed. Accordingly, at least part of the top surface of the EL layer 113 and the top surface of the conductive layer 123 are exposed.

For the removal of the sacrificial layer, a wet etching method is preferably used. With this method, damage given to the EL layer 113 in removal of the sacrificial layer can be reduced as compared to the case where the sacrificial layer is removed by a dry etching method, for example.

The sacrificial layer may be removed by being dissolved in a solvent such as water or alcohol. Examples of alcohol include ethyl alcohol, methyl alcohol, isopropyl alcohol (IPA), and glycerin.

After the sacrificial layers are removed, drying treatment may be performed to remove water included in the EL layer and water adsorbed on the surface of the EL layer. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. Employing a reduced-pressure atmosphere is preferable, in which case drying at a lower temperature is possible.

Next, the common layer 114 is formed over the insulating layer 125, the insulating layer 127, and the EL layer 113. Then, the common electrode 115 is formed over the common layer 114 (FIG. 7C).

The common layer 114 can be formed by an evaporation method (including a vacuum evaporation method), a transfer method, a printing method, an inkjet method, a coating method, or the like. As described above, the common layer 114 can include an electron-injection layer or a hole-injection layer, for example.

The common electrode 115 can be formed by a sputtering method or a vacuum evaporation method, for example. Alternatively, the common electrode 115 may be a stack of a film formed by an evaporation method and a film formed by a sputtering method.

Next, the protective layer 131 is formed over the common electrode 115, and the coloring layers 132R, 132G and 132B are formed over the protective layer 131 (FIG. 7C). In addition, the substrate 120 is attached onto the protective layer 131 and the coloring layers 132R, 132G, and 132B with the resin layer 122, whereby the display apparatus 100 illustrated in FIG. 1B and FIG. 2C can be fabricated.

Examples of methods for forming the protective layer 131 include a vacuum evaporation method, a sputtering method, a CVD method, and an ALD method. The protective layer 131 may have a single-layer structure or a stacked-layer structure.

### [Pixel Layout]

Pixel layouts different from the layout in FIG. 1A will be mainly described below. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and pentile arrangement.

Examples of a top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting device.

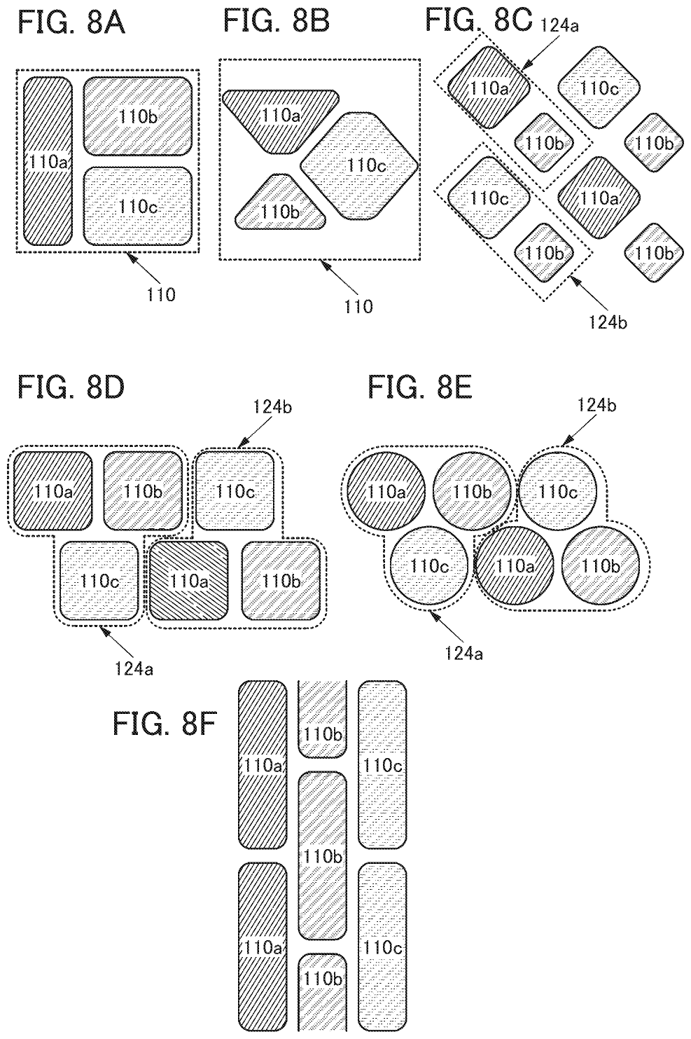

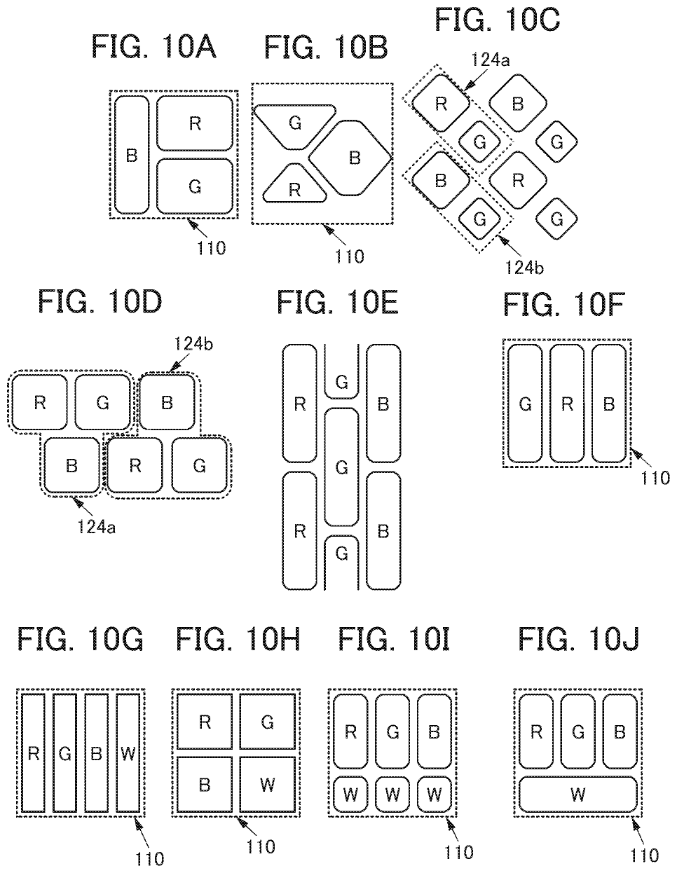

The pixel 110 illustrated in FIG. 8A employs S-stripe arrangement. The pixel 110 illustrated in FIG. 8A is composed of three subpixels 110a, 110b, and 110c. For example, as illustrated in FIG. 10A, the subpixel 110a may be a blue subpixel B, the subpixel 110b may be a red subpixel R, and the subpixel 110c may be a green subpixel G.

The pixel 110 illustrated in FIG. 8B includes the subpixel 110a whose top surface has a rough trapezoidal shape with rounded corners, the subpixel 110b whose top surface has a rough triangle shape with rounded corners, and the subpixel 110c whose top surface has a rough tetragonal or rough hexagonal shape with rounded corners. The subpixel 110a has a larger light-emitting area than the subpixel 110b. In this manner, the shapes and sizes of the subpixels can be determined independently. For example, the size of a subpixel including a light-emitting device with higher reliability can be smaller. For example, as illustrated in FIG. 10B, the subpixel 110a may be the green subpixel G, the subpixel 110b may be the red subpixel R, and the subpixel 110c may be the blue subpixel B.

Pixels 124a and 124b illustrated in FIG. 8C employ pentile arrangement. FIG. 8C illustrates an example in which the pixels 124a including the subpixels 110a and the subpixels 110b and the pixels 124b including the subpixels 110b and the subpixels 110c are alternately arranged. For example, as illustrated in FIG. 10C, the subpixel 110a may be the red subpixel R, the subpixel 110b may be the green subpixel G, and the subpixel 110c may be the blue subpixel B.

The pixels 124a and 124b illustrated in FIG. 8D and FIG. 8E employ delta arrangement. The pixel 124a includes two subpixels (the subpixels 110a and 110b) in the upper row (first row) and one subpixel (the subpixel 110c) in the lower row (second row). The pixel 124b includes one subpixel (the subpixel 110c) in the upper row (first row) and two subpixels (the subpixels 110a and 110b) in the lower row (second row). For example, as illustrated in FIG. 10D, the subpixel 110a may be the red subpixel R, the subpixel 110b may be the green subpixel G, and the subpixel 110c may be the blue subpixel B.

FIG. 8D illustrates an example in which the top surface of each subpixel has a rough tetragonal shape with rounded corners, and FIG. 8E illustrates an example in which the top surface of each subpixel has a circular shape.

FIG. 8F illustrates an example in which subpixels of different colors are arranged in a zigzag manner. Specifically, the positions of the top sides of two subpixels arranged in the column direction (e.g., the subpixel 110a and the subpixel 110b or the subpixel 110b and the subpixel 110c) are not aligned in the top view. For example, as illustrated in FIG. 10E, the subpixel 110a may be the red subpixel R, the subpixel 110b may be the green subpixel G, and the subpixel 110c may be the blue subpixel B.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel can have a polygonal shape with rounded corners, an elliptical shape, a circular shape, or the like.

Furthermore, in the method for fabricating a display apparatus of one embodiment of the present invention, the EL layer is processed into an island shape using a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape when processed. As a result, the top surface of the EL layer may have a polygonal shape with rounded corners, an elliptical shape, a circular shape, or the like. For example, when a resist mask with a square top surface is intended to be formed, a resist mask with a circular top surface may be formed, and the top surface of the EL layer may be circular.

To obtain a desired top surface shape of the EL layer, a technique of correcting a mask pattern in advance so that a design pattern agrees with a transferred pattern (an OPC (Optical Proximity Correction) technique) may be used. Specifically, with the OPC technique, a pattern for correction is added to a corner portion or the like of a figure on a mask pattern.

Note that there is no particular limitation on the arrangement order of subpixels in the pixel 110 employing stripe arrangement illustrated in FIG. 1A; for example, as illustrated in FIG. 10F, the green subpixel G, the red subpixel R, and the blue subpixel B may be arranged in this order.

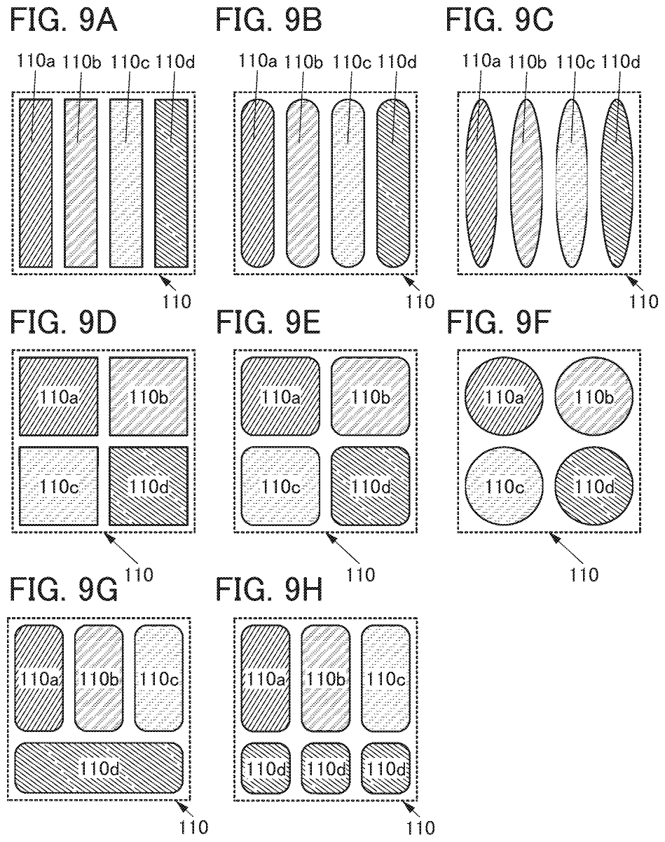

As illustrated in FIG. 9A to FIG. 9H, the pixel can include four types of subpixels.

The pixels 110 illustrated in FIG. 9A to FIG. 9C employ stripe arrangement.

FIG. 9A illustrates an example in which each subpixel has a rectangular top surface shape, FIG. 9B illustrates an example in which each subpixel has a top surface shape formed by combining two half circles and a rectangle, and FIG. 9C illustrates an example in which each subpixel has an elliptical top surface shape.

The pixels 110 illustrated in FIG. 9D to FIG. 9F employ matrix arrangement.

FIG. 9D illustrates an example in which each subpixel has a square top surface shape, FIG. 9E illustrates an example in which each subpixel has a rough square top surface shape with rounded corners, and FIG. 9F illustrates an example in which each subpixel has a circular top surface shape.

FIG. 9G and FIG. 9H each illustrate an example in which one pixel 110 is composed of two rows and three columns.

The pixel 110 illustrated in FIG. 9G includes three subpixels (the subpixels 110a, 110b, and 110c) in the upper row (first row) and one subpixel (a subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 9H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and another subpixel 110d in the center column (second column), and the subpixel 110c and another subpixel 110d in the right column (third column). Aligning the positions of the subpixels in the upper row and the lower row as illustrated in FIG. 9H enables dust and the like that would be produced in the manufacturing process to be removed efficiently. Thus, a display apparatus with high display quality can be provided.

The pixels 110 illustrated in FIG. 9A to FIG. 9H are each composed of the four subpixels 110a, 110b, 110c, and 110d. The subpixels 110a, 110b, 110c, and 110d include light-emitting devices that emit light of different colors. As the subpixels 110a, 110b, 110c, and 110d, subpixels of four colors of R, G, B, and white (W), subpixels of four colors of R, G, B, and Y, subpixels of four colors of R, G, B, and infrared light (IR), and the like can be given. For example, the subpixels 110a, 110b, 110c, and 110d can be red, green, blue, and white subpixels, respectively, as illustrated in FIG. 10G to FIG. 10J.

As described above, the pixel composed of the subpixels each including the light-emitting device can employ any of a variety of layouts in the display apparatus of one embodiment of the present invention.

As described above, in the method for fabricating a display apparatus of this embodiment, the island-shaped EL layers are formed not by using a metal mask having a fine pattern but by processing an EL layer formed over the entire surface. Consequently, the size of the island-shaped EL layer or even the size of the subpixel can be small compared to the case where formation is performed using a metal mask. Accordingly, a high-resolution display apparatus or a display apparatus with a high aperture ratio, which has been difficult to achieve, can be achieved.

In the display apparatus of one embodiment of the present invention, EL layers having the same structure can be used in the subpixels of different colors, so that the number of fabrication steps can be reduced. In the method for fabricating the display apparatus of one embodiment of the present invention, the number of times of processing the EL layer by a photolithography method can be one; thus, the display apparatus can be fabricated with high yield.

This embodiment can be combined with any of the other embodiments as appropriate. In this specification, in the case where a plurality of structure examples are described in one embodiment, the structure examples can be combined as appropriate.

### Embodiment 2

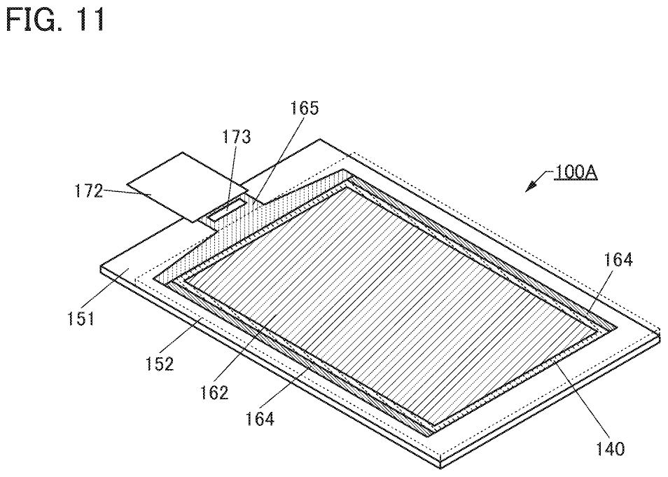

In this embodiment, display apparatuses of one embodiment of the present invention will be described with reference to FIG. 11 to FIG. 14.

The display apparatus of this embodiment can be a high-definition display apparatus or a large-sized display apparatus. Accordingly, the display apparatus of this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Apparatus 100A]

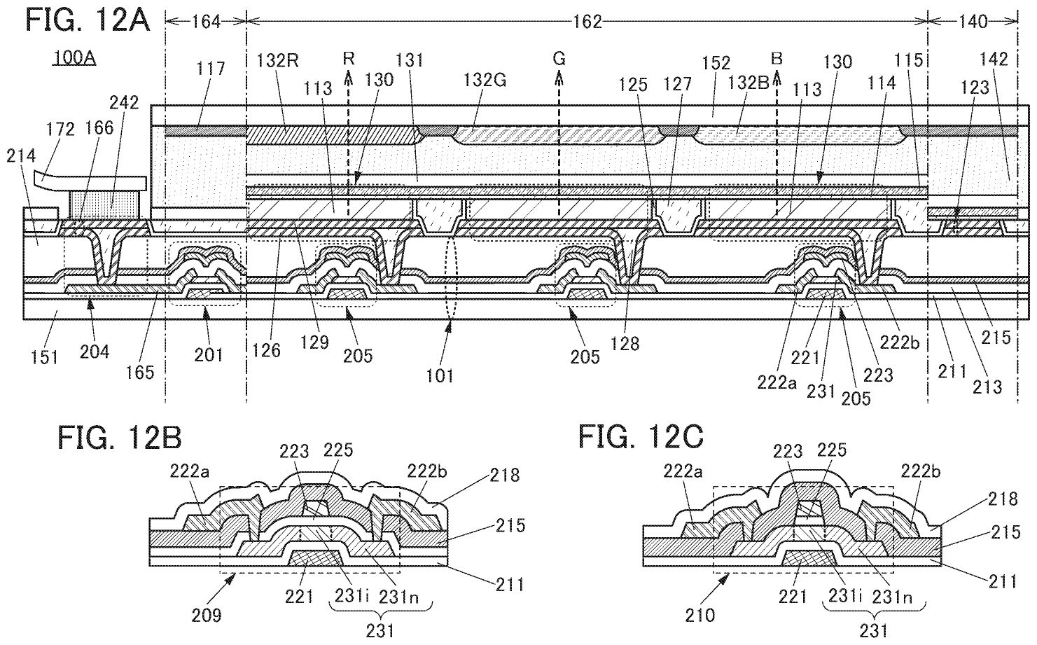

FIG. 11 shows a perspective view of a display apparatus 100A, and FIG. 12A shows a cross-sectional view of the display apparatus 100A.

In the display apparatus 100A, a substrate 152 and a substrate 151 are attached to each other. In FIG. 11, the substrate 152 is denoted by a dashed line.

The display apparatus 100A includes a display portion 162, the connection portion 140, a circuit 164, a wiring 165, and the like. FIG. 11 illustrates an example in which an IC 173 and an FPC 172 are mounted on the display apparatus 100A. Thus, the structure illustrated in FIG. 11 can be regarded as a display module including the display apparatus 100A, the IC (integrated circuit), and the FPC.

The connection portion 140 is provided outside the display portion 162. The connection portion 140 can be provided along one or more sides of the display portion 162. The number of the connection portions 140 may be one or more. FIG. 11 illustrates an example in which the connection portion 140 is provided to surround the four sides of the display portion. The common electrode of the light-emitting device is electrically connected to a conductive layer in the connection portion 140, and thus a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or from the IC 173.

FIG. 11 illustrates an example in which the IC 173 is provided over the substrate 151 by a chip on glass (COG) method, a chip on film (COF) method, or the like. An IC including a scan line driver circuit, a signal line driver circuit, or the like can be used as the IC 173, for example. Note that the display apparatus 100A and the display module are not necessarily provided with an IC. The IC may be mounted on the FPC by a COF method or the like.

FIG. 12A illustrates an example of cross sections of part of a region including the FPC 172, part of the circuit 164, part of the display portion 162, part of the connection portion 140, and part of a region including an end portion of the display apparatus 100A.

The display apparatus 100A illustrated in FIG. 12A includes a transistor 201, a transistor 205, the light-emitting device 130, the coloring layer 132R transmitting red light, the coloring layer 132G transmitting green light, and the coloring layer 132B transmitting blue light, and the like between the substrate 151 and the substrate 152. The light-emitting device 130 can be configured to emit white light. Light emitted by the light-emitting device 130 overlapping with the coloring layer 132R is extracted as red light to the outside of the display apparatus 100A through the coloring layer 132R. Similarly, light emitted by the light-emitting device 130 overlapping with the coloring layer 132G is extracted as green light to the outside of the display apparatus 100A through the coloring layer 132G. Light emitted by the light-emitting device 130 overlapping with the coloring layer 132B is extracted as blue light to the outside of the display apparatus 100A through the coloring layer 132B.

For the display apparatus 100A, the pixel layout shown in Embodiment 1 as an example can be employed.

The light-emitting devices included in subpixels emitting light of different colors can have the same structure, and for example, can be configured to emit white light. Specifically, the EL layers 113 included in the light-emitting devices can have the same structure. In contrast, the EL layers 113 included in the light-emitting devices are separated from each other, which can inhibit generation of leakage current between the light-emitting devices. Thus, the display quality of the display apparatus can be improved.

The light-emitting device 130 has the same structure as the stacked-layer structure illustrated in FIG. 1B except the structure of the pixel electrode. Embodiment 1 can be referred to for the details of the light-emitting device 130.

The light-emitting device 130 includes a conductive layer 126 and a conductive layer 129 over the conductive layer 126. One or both of the conductive layer 126 and the conductive layer 129 can be referred to as a pixel electrode.

The conductive layer 126 is connected to a conductive layer 222b included in the transistor 205 through an opening provided in an insulating layer 214. In the display apparatus 100A, the end portion of the conductive layer 126 and the end portion of the conductive layer 129 are aligned or substantially aligned with each other; however, one embodiment of the present invention is not limited thereto. For example, the conductive layer 129 may be provided so as to cover the end portion of the conductive layer 126.

The conductive layer 126 and the conductive layer 129 each preferably include a conductive layer functioning as a reflective electrode. One or both of the conductive layer 126 and the conductive layer 129 may include a conductive layer functioning as a transparent electrode. For example, it is preferable to use a conductive film reflecting visible light for the conductive layer 126, and to employ a stacked-layer structure of a conductive film reflecting visible light and a conductive film transmitting visible light for the conductive layer 129.

In the case where end portions are aligned or substantially aligned with each other and the case where top surface shapes are the same or substantially the same, it can be said that outlines of stacked layers at least partly overlap with each other in a top view. For example, the case of patterning or partly patterning an upper layer and a lower layer with use of the same mask pattern is included in the expression. However, in some cases, the outlines do not completely overlap with each other and the upper layer is positioned inward from the lower layer or the upper layer is positioned outward from the lower layer; such a case is also represented by the expression “end portions are aligned or substantially aligned with each other” or “top surface shapes are substantially the same”.

The conductive layer 126 is formed to cover the opening provided in the insulating layer 214. A layer 128 is embedded in a depressed portion of the conductive layer 126.

The layer 128 has a planarization function for the depressed portion of the conductive layer 126. The conductive layer 129 electrically connected to the conductive layer 126 is provided over the conductive layer 126 and the layer 128. Thus, a region overlapping with the depressed portion of the conductive layer 126 can also be used as the light-emitting region, increasing the aperture ratio of the pixel.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used as the layer 128. For example, an acrylic resin, a polyimide resin, an epoxy resin, a polyamide resin, a polyimide-amide resin, a siloxane resin, a benzocyclobutene-based resin, a phenol resin, and precursors of these resins can be used for the layer 128. A photosensitive resin can also be used for the layer 128. As the photosensitive resin, a positive photosensitive material or a negative photosensitive material can be used.

When a photosensitive resin is used, the layer 128 can be formed through only light-exposure and development steps, reducing the influence of dry etching, wet etching, or the like on the surfaces of the conductive layer 126. When the layer 128 is formed using a negative photosensitive resin, the layer 128 can sometimes be formed using the same photomask (light-exposure mask) as the photomask used for forming the opening of the insulating layer 214.

The top surface of the conductive layer 129 is covered with the EL layer 113. Accordingly, a region where the conductive layer 129 overlaps with the EL layer 113 in a top view can be entirely used as a light-emitting region of the light-emitting device 130, increasing the aperture ratio of the pixel. Note that the EL layer 113 may cover at least part of the side surface of the conductive layer 129. The EL layer 113 may cover only part of the top surface of the conductive layer 129. In other words, part of the top surface of the conductive layer 129 is not necessarily covered with the EL layer 113.

The side surface of EL layer 113 is covered with the insulating layer 125 and overlaps with the insulating layer 127 with the insulating layer 125 therebetween. The common layer 114 is provided over the EL layer 113, the insulating layer 125, and the insulating layer 127, and the common electrode 115 is provided over the common layer 114. The common layer 114 and the common electrode 115 are each one continuous film provided to be shared by the plurality of light-emitting devices.

The protective layer 131 is provided over the light-emitting device 130. Providing the protective layer 131 covering the light-emitting device can inhibit entry of impurities such as water into the light-emitting device, thereby increasing the reliability of the light-emitting device.

The protective layer 131 and the substrate 152 are bonded to each other with an adhesive layer 142. A solid sealing structure, a hollow sealing structure, or the like can be employed to seal the light-emitting device. In FIG. 12A, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In this case, the adhesive layer 142 may be provided not to overlap with the light-emitting device. Alternatively, the space may be filled with a resin other than the frame-like adhesive layer.

The conductive layer 123 is provided over the insulating layer 214 in the connection portion 140. An example is illustrated in which the conductive layer 123 has a stacked-layer structure of a conductive film obtained by processing the same conductive film as the conductive layer 126 and a conductive film obtained by processing the same conductive film as the conductive layer 129. The side surface of the conductive layer 123 is covered with the insulating layer 125 and overlaps with the insulating layer 127 with the insulating layer 125 provided therebetween. The common layer 114 is provided over the conductive layer 123, and the common electrode 115 is provided over the common layer 114. The conductive layer 123 and the common electrode 115 are electrically connected to each other through the common layer 114. Note that the common layer 114 is not necessarily formed in the connection portion 140. In this case, the conductive layer 123 and the common electrode 115 are directly in contact with each other and electrically connected to each other.

The display apparatus 100A has a top-emission structure. Light emitted by the light-emitting device is emitted toward the substrate 152 side. For the substrate 152, a material having a high visible-light-transmitting property is preferably used.

The pixel electrode contains a material reflecting visible light, and the counter electrode (the common electrode 115) contains a material transmitting visible light.

A stacked-layer structure from the substrate 151 to the insulating layer 214 corresponds to the layer 101 including transistors in Embodiment 1.

The transistor 201 and the transistor 205 are formed over the substrate 151. These transistors can be formed using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material that does not easily allow diffusion of impurities such as water and hydrogen is preferably used for at least one of the insulating layers covering the transistors. This is because such an insulating layer can function as a barrier layer. Such a structure can effectively inhibit diffusion of impurities into the transistors from the outside and improve the reliability of the display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, an aluminum nitride film, or the like can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 214 may have a stacked-layer structure of an organic insulating layer and an inorganic insulating film. The outermost layer of the insulating layer 214 preferably has a function of an etching protective film. Thus, the formation of a depressed portion in the insulating layer 214 can be inhibited in processing the conductive layer 126, the conductive layer 129, or the like. Alternatively, a depressed portion may be formed in the insulating layer 214 in processing the conductive layer 126, the conductive layer 129, or the like.

Each of the transistor 201 and the transistor 205 includes a conductive layer 221 functioning as a gate, the insulating layer 211 functioning as a gate insulating layer, a conductive layer 222a and a conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, an inverted staggered transistor, or the like can be used. A top-gate transistor or a bottom-gate transistor can be used. Alternatively, gates may be provided above and below a semiconductor layer where a channel is formed.

The structure in which the semiconductor layer where a channel is formed is provided between two gates is used for the transistor 201 and the transistor 205. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity because degradation of transistor characteristics can be inhibited.

A semiconductor layer of a transistor preferably includes a metal oxide (also referred to as an oxide semiconductor). That is, a transistor including a metal oxide in its channel formation region (hereinafter, also referred to as an OS transistor) is preferably used for the display apparatus of this embodiment.

As the oxide semiconductor having crystallinity, a CAAC (c-axis aligned crystalline)-OS, an nc (nanocrystalline)-OS, and the like can be given.

Alternatively, a transistor using silicon in a channel formation region (a Si transistor) may be used. Examples of silicon include single crystal silicon, polycrystalline silicon, and amorphous silicon. In particular, a transistor containing low-temperature polysilicon (LTPS) in a semiconductor layer (such a transistor is referred to as an LTPS transistor below) can be used. The LTPS transistor has high field-effect mobility and excellent frequency characteristics.

With use of the Si transistor such as the LTPS transistor, a circuit required to be driven at a high frequency (e.g., a source driver circuit) can be formed on the same substrate as the display portion. This allows simplification of an external circuit mounted on the display apparatus and a reduction in component costs and mounting costs.

The OS transistor has much higher field-effect mobility than a transistor containing amorphous silicon. In addition, the OS transistor has an extremely low leakage current between a source and a drain in an off state (hereinafter, also referred to as an off-state current), and electric charge accumulated in a capacitor that is connected in series to the transistor can be retained for a long period. Furthermore, the power consumption of the display apparatus can be reduced with the OS transistor.

The off-state current per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1× 10⁻²⁴ A). Note that the off-state current per micrometer of channel width of a Si transistor at room temperature is higher than or equal to 1 fA (1×10⁻¹⁵ A) and lower than or equal to 1 pA (1×10⁻¹² A). That is, the off-state current of the OS transistor is lower than the off-state current of the Si transistor by approximately 10 digits.

To increase the emission luminance of the light-emitting device included in a pixel circuit, it is necessary to increase the amount of current flowing through the light-emitting device. For this, it is necessary to increase the source-drain voltage of a driving transistor included in the pixel circuit. Since the OS transistor has a higher withstand voltage between the source and the drain than a Si transistor, a high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When transistors operate in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting device can be controlled. Accordingly, the number of gray levels in the pixel circuit can be increased.

Regarding saturation characteristics of current flowing when transistors operate in a saturation region, even in the case where the source-drain voltage of an OS transistor increases gradually, more stable constant current (saturation current) can be made to flow through the OS transistor than through a Si transistor. Thus, with use of an OS transistor as a driving transistor, current can be made to flow stably through the light-emitting device, for example, even when a variation in current-voltage characteristics of the EL device occurs. In other words, when an OS transistor operates in the saturation region, the source-drain current hardly changes with an increase in the source-drain voltage; hence, the emission luminance of the light-emitting device can be stable.

As described above, with use of an OS transistor as a driving transistor included in the pixel circuit, it is possible to achieve “inhibition of black floating”, “increase in emission luminance”, “increase in the number of gray levels”, “inhibition of variation in light-emitting devices”, and the like.

The metal oxide used in the semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Further alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

When the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide are In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that the neighborhood of the atomic ratio includes ±30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. In addition, when the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. Furthermore, when the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistors included in the circuit 164 and the transistors included in the display portion 162 may have the same structure or different structures. A plurality of transistors included in the circuit 164 may have either the same structure or two or more kinds of structures. Similarly, a plurality of transistors included in the display portion 162 may have either the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both the LTPS transistor and the OS transistor are used in the display portion 162, the display apparatus can have low power consumption and high drive capability. Note that a structure in which the LTPS transistor and the OS transistor are combined is referred to as LTPO in some cases. In a preferred structure example, the OS transistor is used as a transistor or the like functioning as a switch controlling conduction or non-conduction between wirings and the LTPS transistor is used as a transistor or the like controlling current.

For example, one transistor included in the display portion 162 may function as a transistor for controlling current flowing through the light-emitting device and be also referred to as a driving transistor. One of a source and a drain of the driving transistor is electrically connected to the pixel electrode of the light-emitting device. The LTPS transistor is preferably used as the driving transistor. Thus, current flowing through the light-emitting device in the pixel circuit can be increased.

In contrast, another transistor included in the display portion 162 may function as a switch for controlling selection or non-selection of a pixel and can also be referred to as a selection transistor. A gate of the selection transistor is electrically connected to a gate line, and one of a source and a drain thereof is electrically connected to a source line (signal line). The OS transistor is preferably used as the selection transistor. Thus, the gray level of the pixel can be maintained even when the frame frequency is extremely reduced (e.g., 1 fps or lower), whereby power consumption can be reduced by stopping the driver in displaying a still image.

As described above, the display apparatus of one embodiment of the present invention can have all of a high aperture ratio, high resolution, high display quality, and low power consumption.

Note that the display apparatus of one embodiment of the present invention has a structure including the OS transistor and the light-emitting device having an MML (metal maskless) structure. This structure can extremely reduce the leakage current that might flow through a transistor, and the leakage current that might flow between adjacent light-emitting devices (also referred to as a lateral leakage current, a side leakage current, or the like). With the structure, a viewer can notice any one or more of the image crispness, the image sharpness, a high chroma, and a high contrast ratio in an image displayed on the display apparatus. Note that when the leakage current that might flow through a transistor and the lateral leakage current between light-emitting devices are extremely low, display with little leakage of light or the like that might occur in black display can be reduced as much as possible.

FIG. 12B and FIG. 12C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 12B illustrates an example of the transistor 209 in which the insulating layer 225 covers the top surface and the side surface of the semiconductor layer 231. The conductive layer 222a and the conductive layer 222b are connected to the corresponding low-resistance regions 231n through openings provided in the insulating layer 225 and the insulating layer 215. One of the conductive layer 222a and the conductive layer 222b functions as a source, and the other functions as a drain.

In the transistor 210 illustrated in FIG. 12C, the insulating layer 225 overlaps with the channel formation region 231i of the semiconductor layer 231 and does not overlap with the low-resistance regions 231n. The structure illustrated in FIG. 12C can be formed by processing the insulating layer 225 using the conductive layer 223 as a mask, for example. In FIG. 12C, the insulating layer 215 is provided to cover the insulating layer 225 and the conductive layer 223, and the conductive layer 222a and the conductive layer 222b are connected to the corresponding low-resistance regions 231n through the openings in the insulating layer 215.

A connection portion 204 is provided in a region of the substrate 151 not overlapping with the substrate 152. In the connection portion 204, the wiring 165 is electrically connected to the FPC 172 through a conductive layer 166 and a connection layer 242. An example is illustrated in which the conductive layer 166 has a stacked-layer structure of a conductive film obtained by processing the same conductive film as the conductive layer 126 and a conductive film obtained by processing the same conductive film as the conductive layer 129. On the top surface of the connection portion 204, the conductive layer 166 is exposed. Thus, the connection portion 204 and the FPC 172 can be electrically connected to each other through the connection layer 242.

A light-blocking layer 117 is preferably provided on the surface of the substrate 152 on the substrate 151 side. In addition, the coloring layers 132R and 132G may be provided on the surface of the substrate 152 on the substrate 151 side. In FIG. 12A, when the substrate 152 is considered as a reference, the coloring layers 132R and 132G are provided to cover part of the light-blocking layer 117.

The substrate 151 and the substrate 152 can be each formed using any of the materials given in Embodiment 1 as examples of the material that can be used for the substrate 120. In addition, a variety of members that can be placed on the outer surface of the substrate 120 can also be used on the outer surface of the substrate 151 or the substrate 152.

A material that can be used for the resin layer 122 described in Embodiment 1 can be used for the adhesive layer 142.

As the connection layer 242, an anisotropic conductive film (ACF), an anisotropic conductive paste (ACP), or the like can be used.

Examples of materials that can be used for a gate, a source, and a drain of a transistor and conductive layers such as a variety of wirings and electrodes included in a display apparatus include metals such as aluminum, titanium, chromium, nickel, copper, yttrium, zirconium, molybdenum, silver, tantalum, and tungsten, and an alloy containing any of these metals as its main component. A single-layer structure or a stacked-layer structure including a film containing any of these materials can be used.

As a conductive material having a light-transmitting property, a conductive oxide such as indium oxide, indium tin oxide, indium zinc oxide, zinc oxide, or zinc oxide containing gallium, or graphene can be used. It is also possible to use a metal material such as gold, silver, platinum, magnesium, nickel, tungsten, chromium, molybdenum, iron, cobalt, copper, palladium, or titanium or an alloy material containing any of these metal materials. Alternatively, a nitride of the metal material (e.g., titanium nitride) or the like may be used. Note that in the case of using the metal material or the alloy material (or the nitride thereof), the thickness is preferably set small enough to transmit light. Alternatively, stacked films of any of the above materials can be used for the conductive layers. For example, stacked films of indium tin oxide and an alloy of silver and magnesium are preferably used, in which case the conductivity can be increased. These materials can also be used for conductive layers such as wirings and electrodes included in the display apparatus and conductive layers (e.g., a conductive layer functioning as the pixel electrode or the common electrode) included in the light-emitting device.

Examples of insulating materials that can be used for insulating layers include resins such as an acrylic resin and an epoxy resin, and inorganic insulating materials such as silicon oxide, silicon oxynitride, silicon nitride oxide, silicon nitride, and aluminum oxide.

### [Display Apparatus 100B]

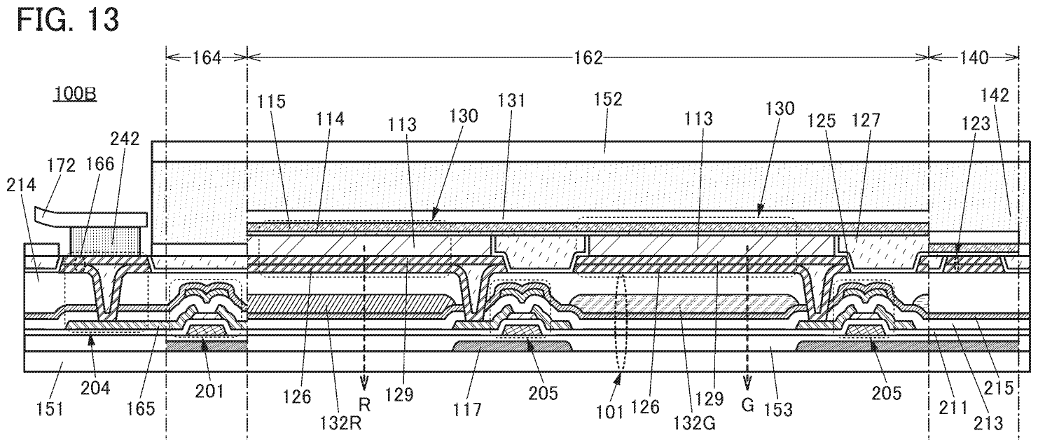

A display apparatus 100B illustrated in FIG. 13 differs from the display apparatus 100A mainly in having a bottom-emission structure. Note that the description of portions similar to those of the display apparatus 100A is omitted.

Light emitted by the light-emitting device is emitted toward the substrate 151 side. For the substrate 151, a material having a high visible-light-transmitting property is preferably used. In contrast, there is no limitation on the light-transmitting property of a material used for the substrate 152.

In the display apparatus 100B, the conductive layer 126 and the conductive layer 129 each contain a material transmitting visible light, and the common electrode 115 contains a material reflecting visible light.

The light-blocking layer 117 is preferably formed between the substrate 151 and the transistor 201 and between the substrate 151 and the transistor 205. FIG. 13 illustrates an example in which the light-blocking layer 117 is provided over the substrate 151, an insulating layer 153 is provided over the light-blocking layer 117, and the transistors 201 and 205 and the like are provided over the insulating layer 153.

Moreover, in the display apparatus 100B, the coloring layer 132R transmitting red light and the coloring layer 132G transmitting green light are provided between the insulating layer 215 and the insulating layer 214. The end portion of the coloring layer 132R and the end portion of the coloring layer 132G each preferably overlap with the light-blocking layer 117. Light emitted by the light-emitting device 130 overlapping with the coloring layer 132R is extracted as red light to the outside of the display apparatus 100B through the coloring layer 132R. Light emitted by the light-emitting device 130 overlapping with the coloring layer 132G is extracted as green light to the outside of the display apparatus 100B through the coloring layer 132G. Although not illustrated, the coloring layer 132B transmitting blue light is also provided between the insulating layer 215 and the insulating layer 214. Light emitted by the light-emitting device 130 overlapping with the coloring layer 132B is extracted as blue light to the outside of the display apparatus 100B through the coloring layer 132B.

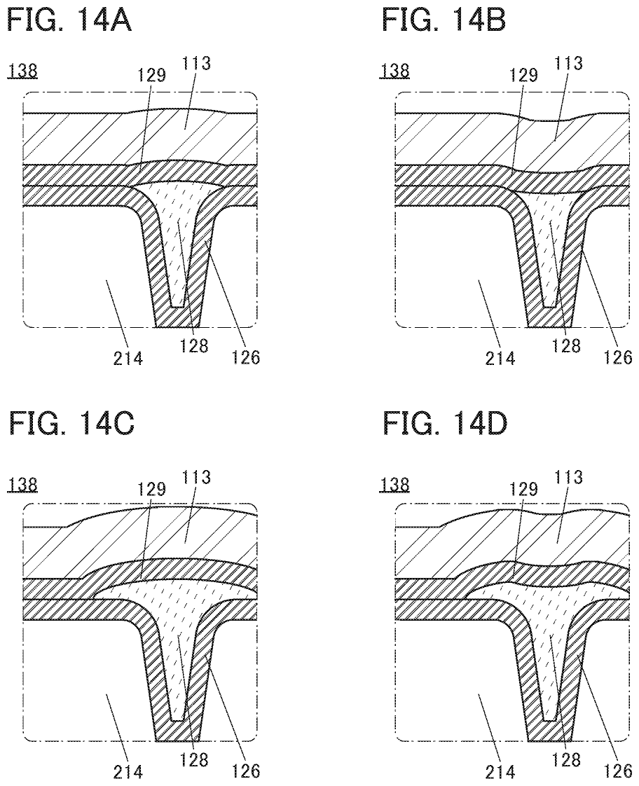

Here, FIG. 14A to FIG. 14D illustrate cross-sectional structures of a region 138 including the conductive layer 126, the layer 128, and the vicinity thereof in the display apparatus 100A and the display apparatus 100B.

FIG. 12A and FIG. 13 each illustrate an example in which the top surface of the layer 128 and the top surface of the conductive layer 126 are substantially level with each other; however, the present invention is not limited to this. For example, as illustrated in FIG. 14A, the top surface of the layer 128 may be at a higher level than that of the conductive layer 126. In this case, the top surface of the layer 128 has a convex shape that is gently bulged toward the center.

As illustrated in FIG. 14B, the top surface of the layer 128 may be at a lower level than that of the conductive layer 126. In this case, the top surface of the layer 128 has a concave shape that is gently recessed toward the center.

When the top surface of the layer 128 is at a higher level than that of the conductive layer 126 as illustrated in FIG. 14C, the upper portion of the layer 128 is formed to be wider than a depressed portion in the conductive layer 126 in some cases. In this case, part of the layer 128 may be formed to cover part of a flat or substantially flat region of the conductive layer 126.

As illustrated in FIG. 14D, the top surface of the layer 128 has a depressed portion in the structure of FIG. 14C, in some cases. The depressed portion has a shape that is gently recessed toward the center.

This embodiment can be combined with any of the other embodiments as appropriate.

### Embodiment 3

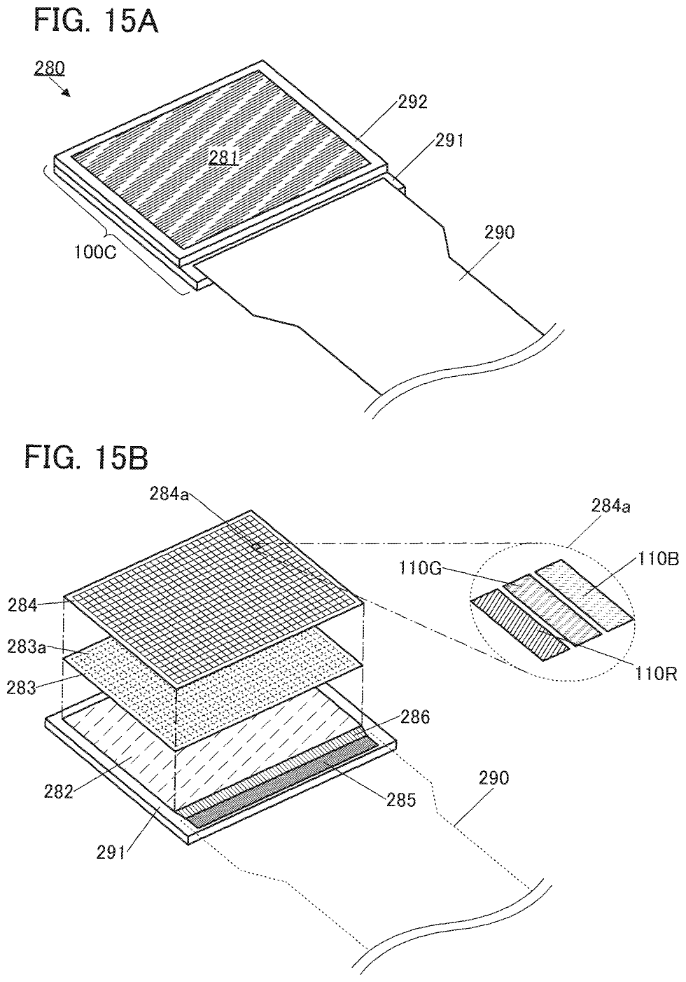

In this embodiment, display apparatuses of one embodiment of the present invention will be described with reference to FIG. 15 to FIG. 20.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices that can be worn on a head, such as a VR device like a head-mounted display and a glasses-type AR device.

### [Display Module]

FIG. 15A shows a perspective view of a display module 280. The display module 280 includes a display apparatus 100C and an FPC 290. Note that the display apparatus included in the display module 280 is not limited to the display apparatus 100C and may be any of a display apparatus 100D to a display apparatus 100G described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 15B shows a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion that is over the substrate 291 and does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 15B. The pixel 284a includes the subpixel 110R exhibiting red light, the subpixel 110G exhibiting green light, and the subpixel 110B exhibiting blue light arranged in this order. Embodiment 1 can be referred to for a pixel layout that can be employed for the pixel portion 284.

The pixel circuit portion 283 includes a plurality of pixel circuits 283a arranged periodically.

One pixel circuit 283a is a circuit that controls light emission by three light-emitting devices included in one pixel 284a. One pixel circuit 283a may be provided with three circuits each controlling light emission by one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. With such a structure, an active-matrix display apparatus is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like. The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (the effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have extremely high resolution. For example, the pixels 284a are preferably arranged in the display portion 281 with a resolution 2000 ppi or higher, preferably 3000 ppi or higher, further preferably 5000 ppi or higher, still further preferably 6000 ppi or higher, and 20000 ppi or lower or 30000 ppi or lower.

Such a display module 280 has extremely high resolution, and thus can be suitably used for a VR device such as a head-mounted display or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used for a display portion of a wearable electronic device, such as a wrist watch.

### [Display Apparatus 100C]

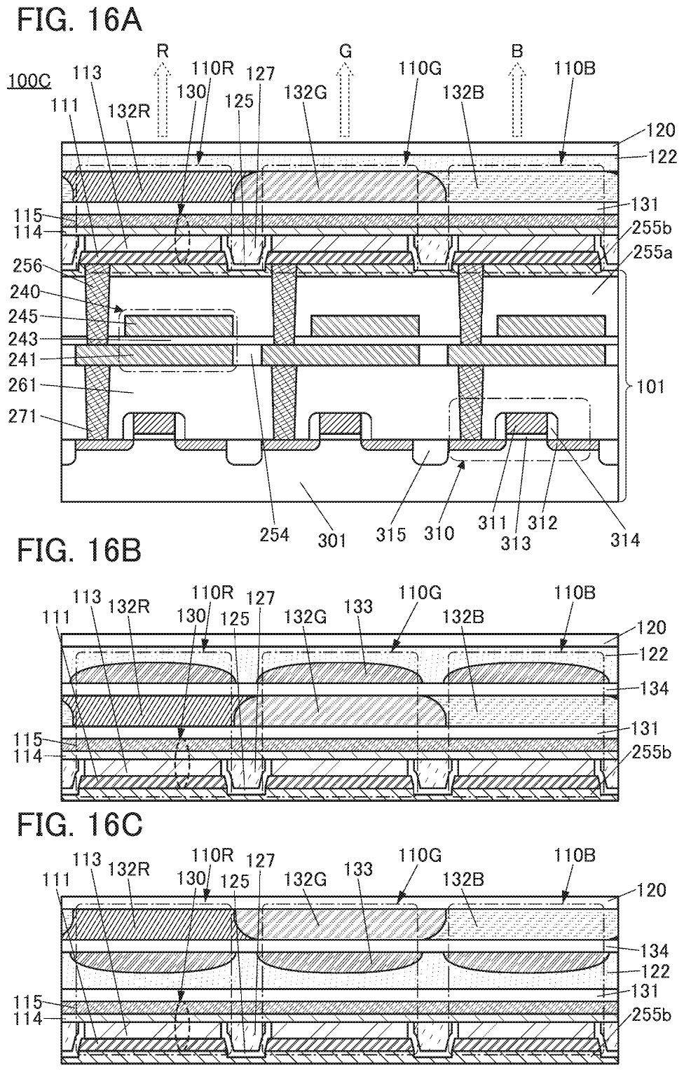

The display apparatus 100C illustrated in FIG. 16A includes a substrate 301, the light-emitting device 130, the coloring layer 132R, the coloring layer 132G, the coloring layer 132B, a capacitor 240, a transistor 310, and the like. The subpixel 110R includes the light-emitting device 130 and the coloring layer 132R, the subpixel 110G includes the light-emitting device 130 and the coloring layer 132G, and the subpixel 110B includes the light-emitting device 130 and the coloring layer 132B. The light-emitting device 130 can be configured to emit white light. In the subpixel 110R, light emitted by the light-emitting device 130 is extracted as red light to the outside of the display apparatus 100C through the coloring layer 132R. In the subpixel 110G, light emitted by the light-emitting device 130 is extracted as green light to the outside of the display apparatus 100C through the coloring layer 132G. In the subpixel 110B, light emitted by the light-emitting device 130 is extracted as blue light to the outside of the display apparatus 100C through the coloring layer 132B.

The light-emitting devices included in subpixels emitting light of different colors can have the same structure, and for example, can be configured to emit white light. Specifically, the EL layers 113 included in the light-emitting devices can have the same structure. In contrast, the EL layers 113 included in the light-emitting devices are separated from each other, which can inhibit generation of leakage current between light-emitting devices. Thus, the display quality of the display apparatus can be improved.

The substrate 301 corresponds to the substrate 291 illustrated in FIG. 15A and FIG. 15B. A stacked-layer structure from the substrate 301 to the insulating layer 255b corresponds to the layer 101 including transistors in Embodiment 1.

The transistor 310 includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, and the insulating layer 255b is provided over the insulating layer 255a.

As each of the insulating layer 255a and the insulating layer 255b, a variety of inorganic insulating films such as an oxide insulating film, a nitride insulating film, an oxynitride insulating film, and a nitride oxide insulating film can be suitably used. As the insulating layer 255a, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferable that a silicon oxide film be used as the insulating layer 255a and a silicon nitride film be used as the insulating layer 255b. The insulating layer 255b preferably has a function of an etching protective film. Alternatively, a nitride insulating film or a nitride oxide insulating film may be used as the insulating layer 255a, and an oxide insulating film or an oxynitride insulating film may be used as the insulating layer 255b. Although this embodiment describes an example in which a depressed portion is provided in the insulating layer 255b, a depressed portion is not necessarily provided in the insulating layer 255b.

The light-emitting device 130 is provided over the insulating layer 255b. This embodiment describes an example where the light-emitting device 130 has a structure similar to the stacked-layer structure illustrated in FIG. 1B. The side surface of the pixel electrode 111 and the side surface of the EL layer 113 are each covered with the insulating layer 125 and overlap with the insulating layer 127 with the insulating layer 125 therebetween. The common layer 114 is provided over the EL layer 113, the insulating layer 125, and the insulating layer 127, and the common electrode 115 is provided over the common layer 114.

The pixel electrode 111 of the light-emitting device is electrically connected to one of the source and the drain of the transistor 310 through a plug 256 embedded in the insulating layer 255a and the insulating layer 255b, the conductive layer 241 embedded in the insulating layer 254, and the plug 271 embedded in the insulating layer 261. The top surface of the insulating layer 255b and the top surface of the plug 256 are level or substantially level with each other. A variety of conductive materials can be used for the plugs.

The protective layer 131 is provided over the light-emitting device 130. The coloring layers 132R, 132G, and 132B are provided over the protective layer 131. The substrate 120 is attached onto the coloring layers 132R, 132G, and 132B with the resin layer 122. Embodiment 1 can be referred to for the details of the light-emitting devices and the components thereover up to the substrate 120. The substrate 120 corresponds to the substrate 292 in FIG. 15A.

As illustrated in FIG. 16B and FIG. 16C, a lens array 133 may be provided. Using the lens array 133 enables light emitted from the light-emitting device 130 to be collected.

FIG. 16B illustrates an example in which the coloring layers 132R, 132G, and 132B are provided over the light-emitting devices 130 with the protective layer 131 therebetween, an insulating layer 134 is provided over the coloring layers 132R, 132G, and 132B, and the lens array 133 is provided over the insulating layer 134. The coloring layer 132R, the coloring layer 132G, the coloring layer 132B, and the lens array 133 are directly formed over the substrate provided with the light-emitting devices 130, whereby the accuracy of positional alignment of the light-emitting devices and the coloring layers or the lens array can be enhanced.

For the insulating layer 134, one or both of an inorganic insulating film and an organic insulating film can be used. The insulating layer 134 may have either a single-layer structure or a stacked-layer structure. The insulating layer 134 can be formed using a material that can be used for the protective layer 131, for example. When light emitted by the light-emitting device is extracted through the insulating layer 134, the insulating layer 134 preferably has a high visible-light-transmitting property.

In FIG. 16B, light emitted by the light-emitting device 130 passes through the coloring layer and then passes through the lens array 133, resulting in being extracted to the outside of the display apparatus. It is preferable to shorten the distance between the light-emitting device and the coloring layer because color mixing can be inhibited and the viewing angle characteristics can be improved. Note that a structure in which the lens array 133 is provided over the light-emitting device 130 and the coloring layer is provided over the lens array 133 may be employed.

FIG. 16C illustrates an example in which the substrate 120 provided with the coloring layer 132R, the coloring layer 132G, the coloring layer 132B, and the lens array 133 is attached onto the protective layer 131 with the resin layer 122. The substrate 120 is provided with the coloring layer 132R, the coloring layer 132G, the coloring layer 132B, and the lens array 133, whereby the heat treatment temperature in the forming step of them can be increased.

In the example of FIG. 16C, the coloring layers 132R, 132G, and 132B are provided in contact with the substrate 120, the insulating layer 134 is provided in contact with the coloring layers 132R, 132G, and 132B, and the lens array 133 is provided in contact with the insulating layer 134.

In FIG. 16C, light emitted by the light-emitting device 130 passes through the lens array 133 and then passes through the coloring layer, resulting in being extracted to the outside of the display apparatus. Note that a structure in which the lens array 133 is provided in contact with the substrate 120, the insulating layer 134 is provided in contact with the lens array 133, and the coloring layers are provided in contact with the insulating layer 134 may be employed. In this case, light emitted by the light-emitting device 130 passes through the coloring layer and then passes through the lens array 133, resulting in being extracted to the outside of the display apparatus.

The lens array 133 may have a convex surface facing the substrate 120 side or a convex surface facing the light-emitting device 130 side.

The lens array 133 can be formed using at least one of an inorganic material and an organic material. For example, a material containing a resin can be used for the lens. Moreover, a material containing at least one of an oxide and a sulfide can be used for the lens. As the lens array 133, a microlens array can be used, for example. The lens array 133 may be directly formed over the substrate or the light-emitting device. Alternatively, a lens array separately formed may be attached thereto.

### [Display Apparatus 100D]

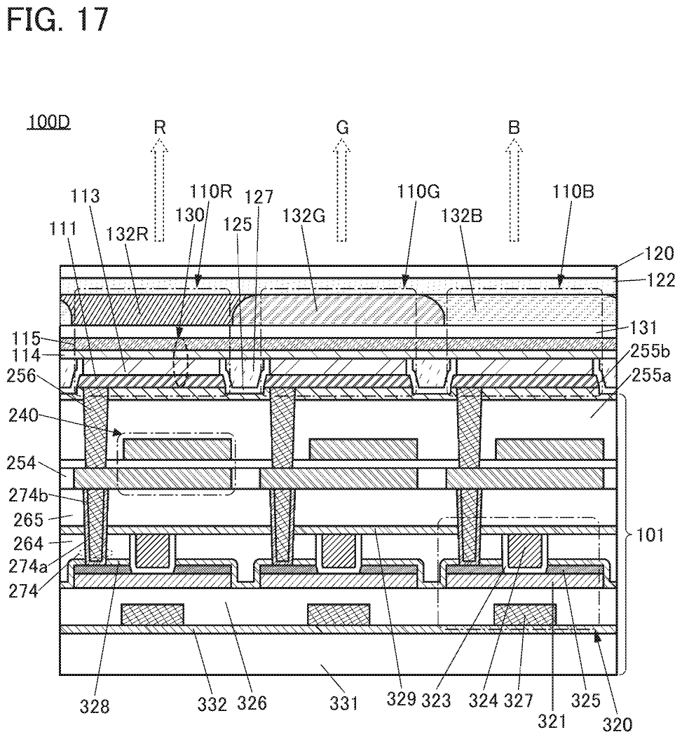

The display apparatus 100D illustrated in FIG. 17 differs from the display apparatus 100C mainly in a structure of a transistor. Note that in the following description of display apparatuses, the description of portions similar to those of the above-described display apparatuses may be omitted.

A transistor 320 is a transistor that includes a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 illustrated in FIG. 15A and FIG. 15B. A stacked-layer structure from the substrate 331 to the insulating layer 255b corresponds to the layer 101 including transistors in Embodiment 1. As the substrate 331, an insulating substrate or a semiconductor substrate can be used.

An insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, it is possible to use, for example, a film in which hydrogen or oxygen is less likely to diffuse than in a silicon oxide film, such as an aluminum oxide film, a hafnium oxide film, or a silicon nitride film.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. A metal oxide (also referred to as an oxide semiconductor) film having semiconductor characteristics is preferably used as the semiconductor layer 321.

The pair of conductive layers 325 is provided over and in contact with the semiconductor layer 321, and functions as a source electrode and a drain electrode.

An insulating layer 328 is provided to cover the top and the side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water and hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325, and the top surface of the semiconductor layer 321 and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are subjected to planarization treatment to be level or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water and hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a covering the side surfaces of openings in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material that does not easily allow diffusion of hydrogen and oxygen is preferably used.

The structures of the insulating layer 254 and the components thereover up to the substrate 120 in the display apparatus 100D are similar to those in the display apparatus 100C.

### [Display Apparatus 100E]

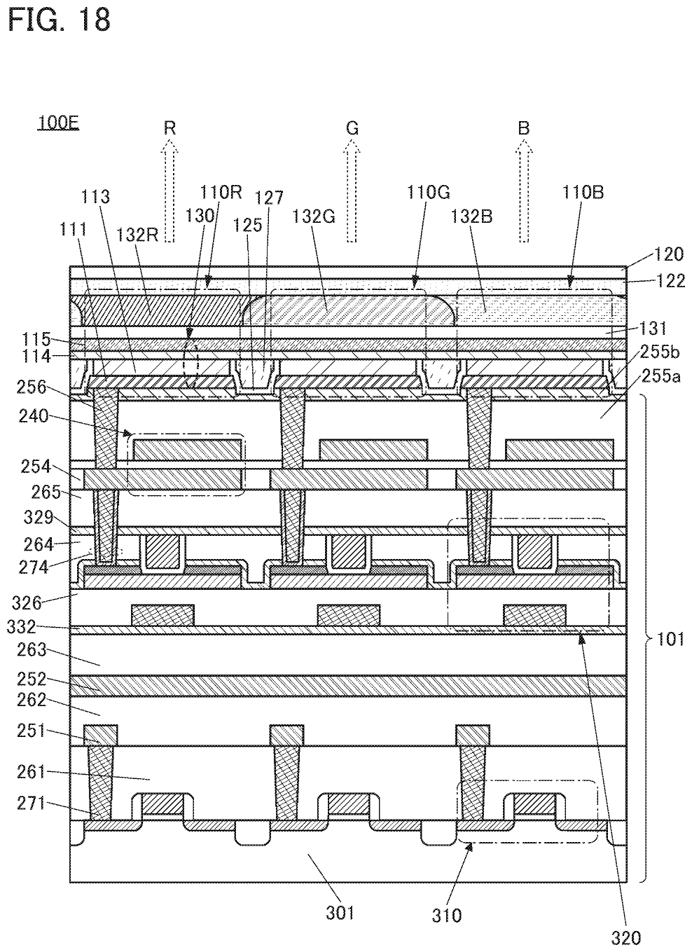

The display apparatus 100E illustrated in FIG. 18 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices; thus, the display apparatus can be downsized as compared with the case where a driver circuit is provided around a display region.

### [Display Apparatus 100F]

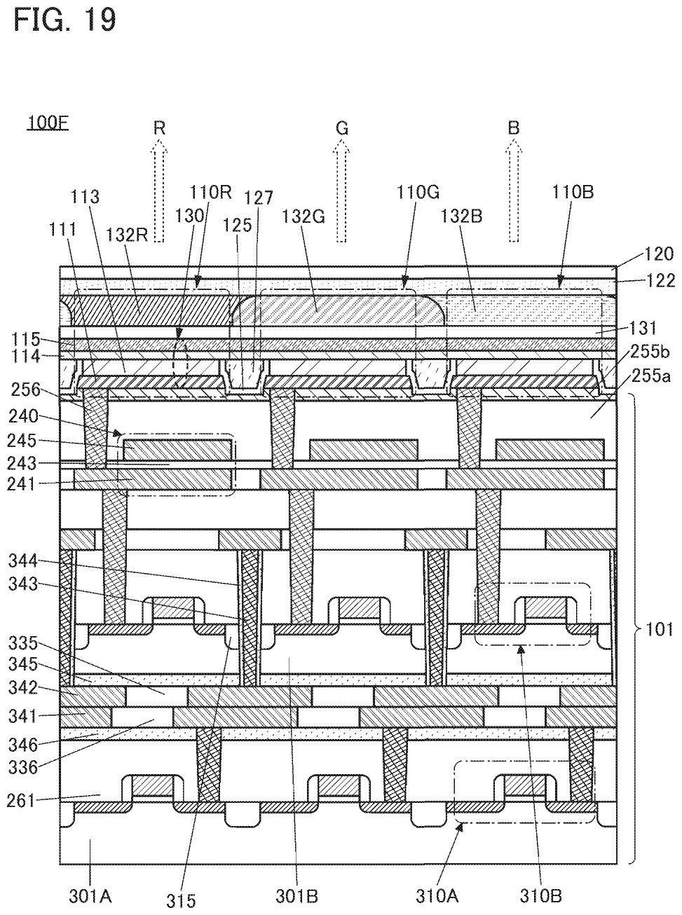

The display apparatus 100F illustrated in FIG. 19 has a structure where a transistor 310A and a transistor 310B in each of which a channel is formed in a semiconductor substrate are stacked.

In the display apparatus 100F, a substrate 301B provided with the transistor 310B, the capacitor 240, and the light-emitting devices is attached to a substrate 301A provided with the transistor 310A.

Here, an insulating layer 345 is preferably provided on the bottom surface of the substrate 301B. An insulating layer 346 is preferably provided over the insulating layer 261 over the substrate 301A. The insulating layers 345 and 346 function as protective layers and can inhibit diffusion of impurities into the substrate 301B and the substrate 301A. As the insulating layers 345 and 346, an inorganic insulating film that can be used as the protective layer 131 can be used.

The substrate 301B is provided with a plug 343 that penetrates the substrate 301B and the insulating layer 345. Here, an insulating layer 344 is preferably provided to cover the side surface of the plug 343. The insulating layer 344 functions as a protective layer and can inhibit diffusion of impurities into the substrate 301B. As the insulating layer 344, an inorganic insulating film that can be used as the protective layer 131 can be used.

A conductive layer 342 is provided under the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

A conductive layer 341 is provided over the insulating layer 346 over the substrate 301A. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be attached to each other favorably.

The conductive layer 341 and the conductive layer 342 are preferably formed using the same conductive material. For example, a metal film containing an element selected from Al, Cr, Cu, Ta, Ti, Mo, and W, or a metal nitride film containing any of the above elements as a component (a titanium nitride film, a molybdenum nitride film, or a tungsten nitride film) can be used. Copper is particularly preferably used for the conductive layer 341 and the conductive layer 342. In that case, it is possible to employ a Cu-to-Cu (copper-to-copper) direct bonding technique (a technique for achieving electrical continuity by connecting Cu (copper) pads).

### [Display Apparatus 100G]

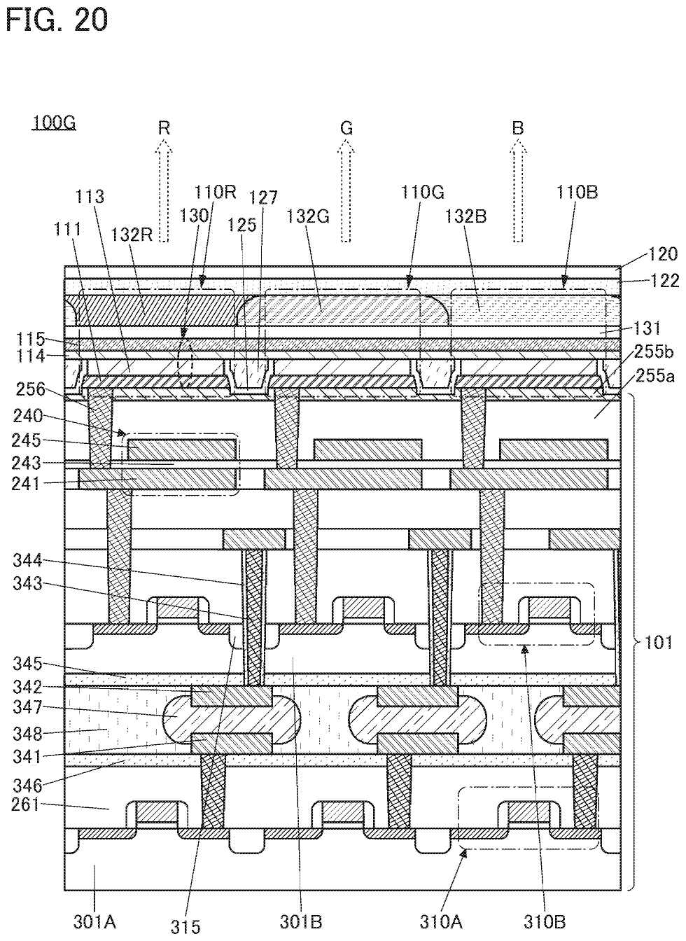

Although FIG. 19 illustrates an example in which Cu-to-Cu direct bonding technique is used to bond the conductive layer 341 and the conductive layer 342, the present invention is not limited thereto. As illustrated in FIG. 20, the conductive layer 341 and the conductive layer 342 may be bonded to each other through a bump 347 in the display apparatus 100G.

As illustrated in FIG. 20, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

This embodiment can be combined with any of the other embodiments as appropriate.

### Embodiment 4

In this embodiment, a light-emitting device that can be used for the display apparatus of one embodiment of the present invention will be described.

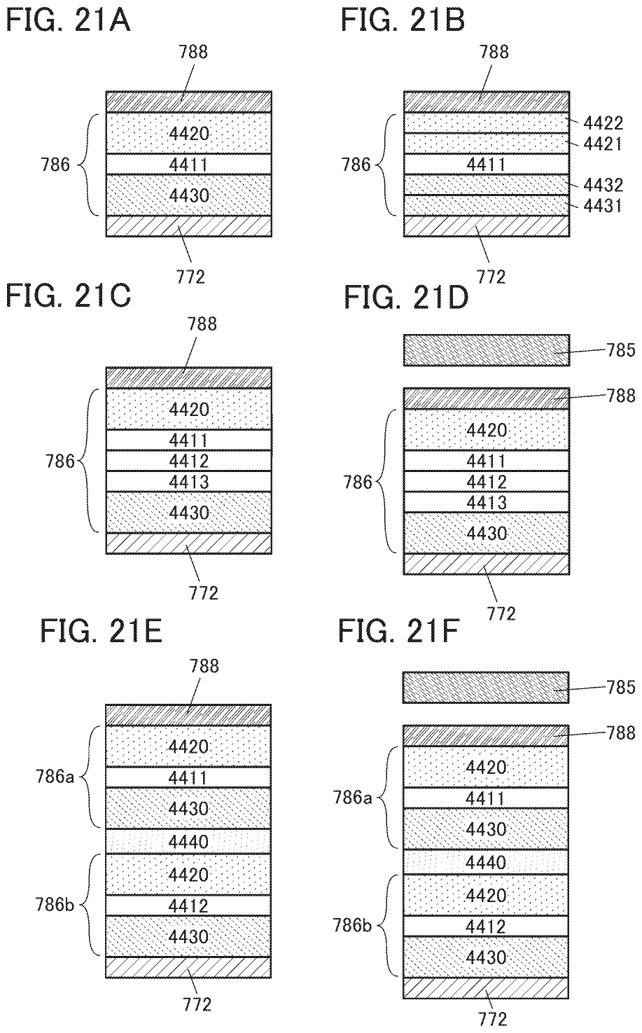

As illustrated in FIG. 21A, the light-emitting device includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between a pair of electrodes, can function as a single light-emitting unit, and the structure in FIG. 21A is referred to as a single structure in this specification.

FIG. 21B is a variation example of the EL layer 786 included in the light-emitting device illustrated in FIG. 21A. Specifically, the light-emitting device illustrated in FIG. 21B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. For example, when the lower electrode 772 is an anode and the upper electrode 788 is a cathode, the layer 4431 functions as a hole-injection layer, the layer 4432 functions as a hole-transport layer, the layer 4421 functions as an electron-transport layer, and the layer 4422 functions as an electron-injection layer. Alternatively, when the lower electrode 772 is a cathode and the upper electrode 788 is an anode, the layer 4431 functions as an electron-injection layer, the layer 4432 functions as an electron-transport layer, the layer 4421 functions as a hole-transport layer, and the layer 4422 functions as a hole-injection layer. With such a layered structure, carriers can be efficiently injected into the light-emitting layer 4411, and the efficiency of the recombination of carriers in the light-emitting layer 4411 can be enhanced.

Note that structures in which a plurality of light-emitting layers (light-emitting layers 4411, 4412, and 4413) are provided between the layer 4420 and the layer 4430 as illustrated in FIG. 21C and FIG. 21D are other variations of the single structure.

A structure in which a plurality of light-emitting units (an EL layer 786a and an EL layer 786b) are connected in series with a charge-generation layer 4440 therebetween as illustrated in FIG. 21E and FIG. 21F is referred to as a tandem structure in this specification. A tandem structure may be referred to as a stack structure. The tandem structure enables a light-emitting device capable of high luminance light emission.

In FIG. 21C and FIG. 21D, light-emitting materials emitting light of the same color, or moreover, the same light-emitting material may be used for the light-emitting layer 4411, the light-emitting layer 4412, and the light-emitting layer 4413. For example, a light-emitting material emitting blue light may be used for the light-emitting layer 4411, the light-emitting layer 4412, and the light-emitting layer 4413. A color conversion layer may be provided as a layer 785 illustrated in FIG. 21D.

Alternatively, light-emitting materials emitting light of different colors may be used for the light-emitting layer 4411, the light-emitting layer 4412, and the light-emitting layer 4413. White light can be obtained when the light-emitting layer 4411, the light-emitting layer 4412, and the light-emitting layer 4413 emit light of complementary colors. A color filter (also referred to as a coloring layer) may be provided as the layer 785 illustrated in FIG. 21D. When white light passes through a color filter, light of a desired color can be obtained.

In FIG. 21E and FIG. 21F, light-emitting materials emitting light of the same color, or moreover, the same light-emitting material may be used for the light-emitting layer 4411 and the light-emitting layer 4412. Alternatively, light-emitting materials emitting light of different colors may be used for the light-emitting layer 4411 and the light-emitting layer 4412. White light can be obtained when the light-emitting layer 4411 and the light-emitting layer 4412 emit light of complementary colors. FIG. 21F illustrates an example in which the layer 785 is further provided. One or both of a color conversion layer and a color filter (a coloring layer) can be used as the layer 785.

In FIG. 21C, FIG. 21D, FIG. 21E, and FIG. 21F, the layer 4420 and the layer 4430 may each have a stacked-layered structure of two or more layers as in FIG. 21B.

A structure in which light-emitting devices of different emission colors (e.g., blue (B), green (G), and red (R)) are separately formed is referred to as an SBS (Side By Side) structure in some cases.

The emission color of the light-emitting device can be changed to red, green, blue, cyan, magenta, yellow, white, or the like depending on the material of the EL layer 786. When the light-emitting device has a microcavity structure, the color purity can be further increased.

In the light-emitting device emitting white light, the light-emitting layer preferably contains two or more kinds of light-emitting materials. For example, when an emission color of a first light-emitting layer and an emission color of a second light-emitting layer are complementary colors, the light-emitting device can be configured to emit white light as a whole. In the case where three or more light-emitting layers are used to obtain white light emission, a light-emitting device is configured to emit white light as a whole by combining emission colors of the three or more light-emitting layers.

The light-emitting layer preferably contains two or more selected from light-emitting materials emitting light of R (red), G (green), B (blue), Y (yellow), O (orange), and the like. Alternatively, the light-emitting layer preferably contains two or more light-emitting materials emitting light containing two or more of spectral components of R, G, and B.

This embodiment can be combined with any of the other embodiments as appropriate.

### Embodiment 5

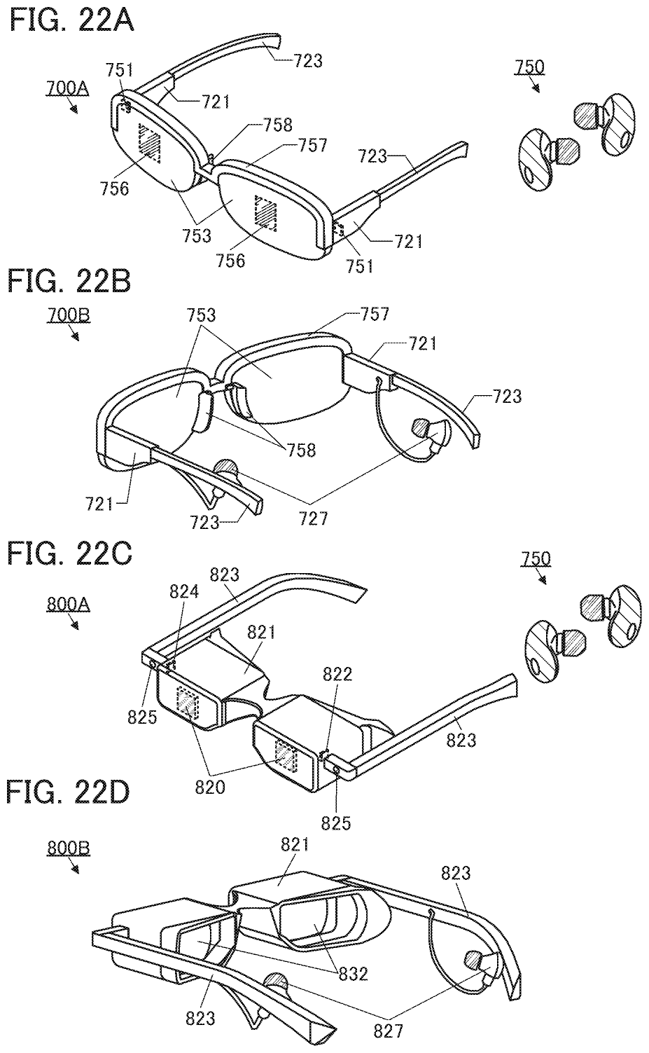

In this embodiment, electronic devices of one embodiment of the present invention will be described with reference to FIG. 22 to FIG. 25.

Electronic devices of this embodiment each include the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display apparatus of one embodiment of the present invention can have a high resolution, and thus can be suitably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With the use of the display apparatus having one or both of such high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device of this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of this embodiment can have a variety of functions. For example, the electronic device of this embodiment can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIG. 22A to FIG. 22D. These wearable devices have one or both of a function of displaying AR contents and a function of displaying VR contents. Note that these wearable devices may have a function of displaying SR or MR contents, in addition to AR and VR contents. The electronic device having a function of displaying contents of AR, VR, SR, MR, or the like enables the user to feel a higher sense of immersion.

An electronic device 700A illustrated in FIG. 22A and an electronic device 700B illustrated in FIG. 22B each include a pair of display panels 751, a pair of housings 721, a communication portion (not illustrated), a pair of mounting portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic devices are capable of performing ultrahigh-resolution display.

The electronic device 700A and the electronic device 700B can each project images displayed on the display panels 751 onto display regions 756 of the optical members 753. Since the optical members 753 have a light-transmitting property, the user can see images displayed on the display regions 756, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be detected and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, processing such as pausing or restarting a video can be executed by a tap operation, and processing such as fast-forwarding or fast-rewinding can be executed by a slide operation. When the touch sensor module is provided in each of the two housings 721, the range of the operation can be increased.

Various touch sensors can be used for the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 22C and an electronic device 800B illustrated in FIG. 22D each include a pair of display portions 820, a housing 821, a communication portion 822, a pair of mounting portions 823, a control portion 824, a pair of image capturing portions 825, and a pair of lenses 832.

The display apparatus of one embodiment of the present invention can be used for the display portions 820. Thus, the electronic devices are capable of performing ultrahigh-resolution display. Such electronic devices can provide a high sense of immersion to the user.

The display portions 820 are positioned inside the housing 821 so as to be seen through the lenses 832. When the pair of display portions 820 display different images, three-dimensional display using parallax can also be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the mounting portions 823. FIG. 22C and the like illustrate examples where the mounting portion 823 has a shape like a temple (also referred to as a joint or the like) of glasses; however, one embodiment of the present invention is not limited thereto. The mounting portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is described here, a range sensor capable of measuring a distance between the user and an object (hereinafter also referred to as a detecting portion) just needs to be provided. In other words, the image capturing portion 825 is one embodiment of the detecting portion. As the detecting portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the mounting portion 823 can include the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and has a wireless communication function. The earphones 750 can receive information (e.g., audio data) from the electronic device with the wireless communication function. For example, the electronic device 700A in FIG. 22A has a function of transmitting information to the earphones 750 with the wireless communication function. As another example, the electronic device 800A in FIG. 22C has a function of transmitting information to the earphones 750 with the wireless communication function.

The electronic device may include an earphone portion. The electronic device 700B in FIG. 22B includes earphone portions 727. For example, the earphone portion 727 can be connected to the control portion by wire. Part of a wiring that connects the earphone portion 727 and the control portion may be positioned inside the housing 721 or the mounting portion 723.

Similarly, the electronic device 800B in FIG. 22D includes earphone portions 827. For example, the earphone portion 827 can be connected to the control portion 824 by wire. Part of a wiring that connects the earphone portion 827 and the control portion 824 may be positioned inside the housing 821 or the mounting portion 823. Alternatively, the earphone portions 827 and the mounting portions 823 may include magnets. This is preferred because the earphone portions 827 can be fixed to the mounting portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

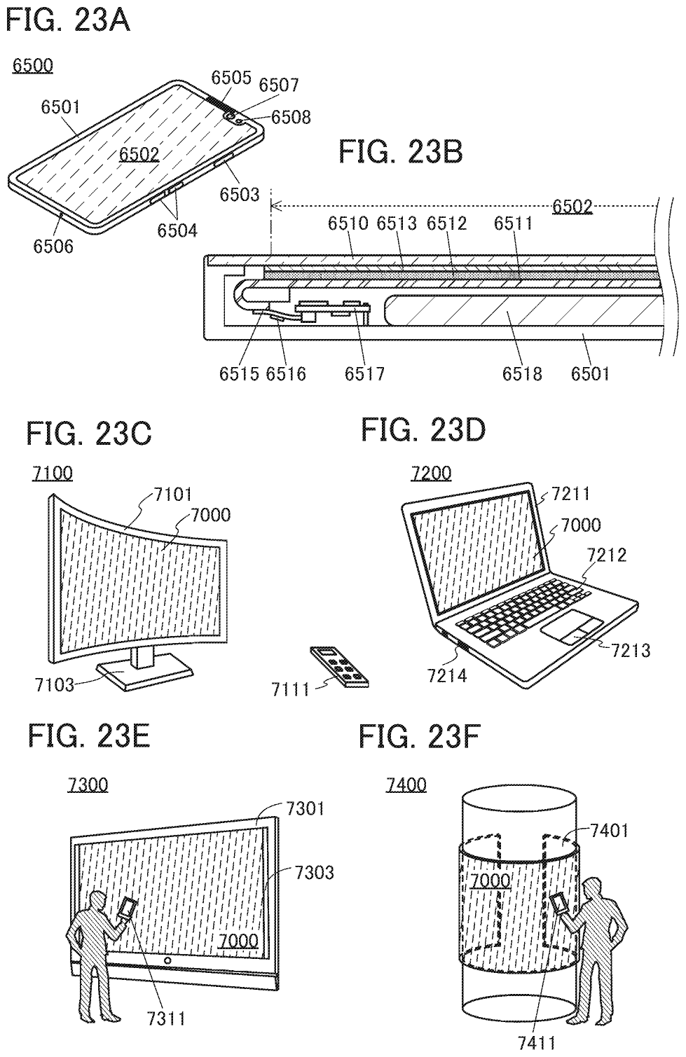

An electronic device 6500 illustrated in FIG. 23A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 23B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while an increase in the thickness of the electronic device is suppressed. Moreover, part of the display panel 6511 is folded back so that a connection portion with the FPC 6515 is placed on the back side of the pixel portion, whereby an electronic device with a narrow bezel can be achieved.

FIG. 23C illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 23C can be performed with an operation switch provided in the housing 7101 and a separate remote controller 7111. Alternatively, the display portion 7000 may be provided with a touch sensor, and the television device 7100 may be operated by touch on the display portion 7000 with a finger or the like. The remote controller 7111 may include a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 23D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used for the display portion 7000.

FIG. 23E and FIG. 23F illustrate examples of digital signage.

Digital signage 7300 illustrated in FIG. 23E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 23F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 illustrated in each of FIG. 23E and FIG. 23F.

A larger area of the display portion 7000 can increase the amount of data that can be provided at a time. The larger display portion 7000 attracts more attention, so that the effectiveness of the advertisement can be increased, for example.

The use of a touch panel in the display portion 7000 is preferable because in addition to display of an image or a moving image on the display portion 7000, intuitive operation by a user is possible. Moreover, for an application for providing information such as route information or traffic information, usability can be enhanced by intuitive operation.

As illustrated in FIG. 23E and FIG. 23F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

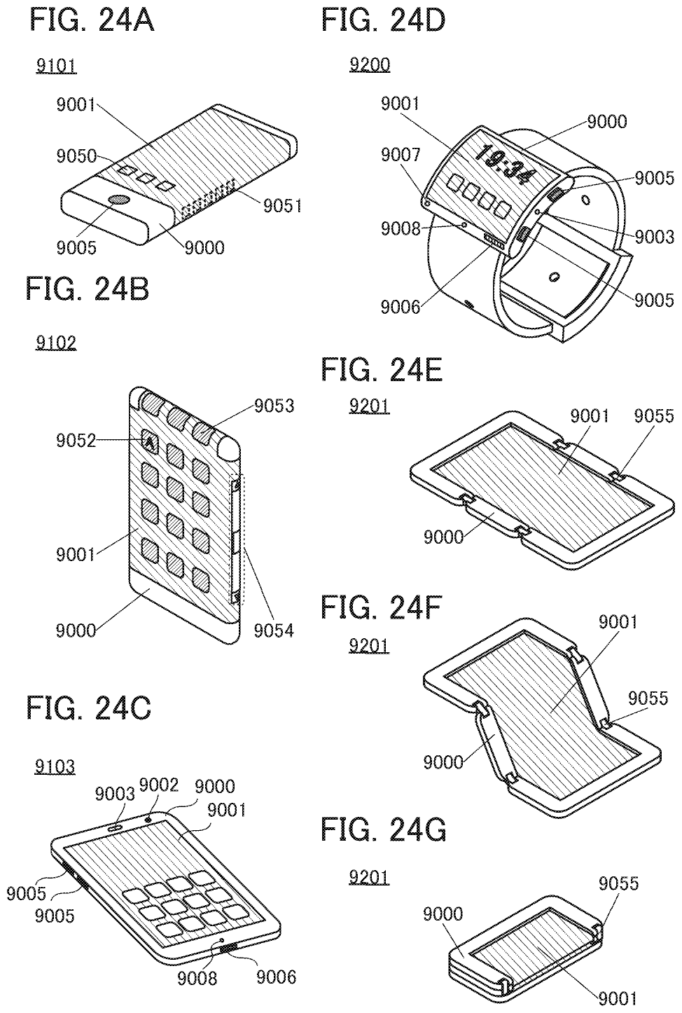

Electronic devices illustrated in FIG. 24A to FIG. 24G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, oscillation, odor, or infrared rays), a microphone 9008, and the like.

In FIG. 24A to FIG. 24G, the display apparatus of one embodiment of the present invention can be used for the display portion 9001.

The electronic devices illustrated in FIG. 24A to FIG. 24G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices illustrated in FIG. 24A to FIG. 24G will be described in detail below.

FIG. 24A is a perspective view illustrating a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 24A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 24B is a perspective view illustrating a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 24C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 24D is a perspective view illustrating a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 24E to FIG. 24G are perspective views illustrating a foldable portable information terminal 9201. FIG. 24E is a perspective view of an opened state of the portable information terminal 9201, FIG. 24G is a perspective view of a folded state thereof, and FIG. 24F is a perspective view of a state in the middle of change from one of FIG. 24E and FIG. 24G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

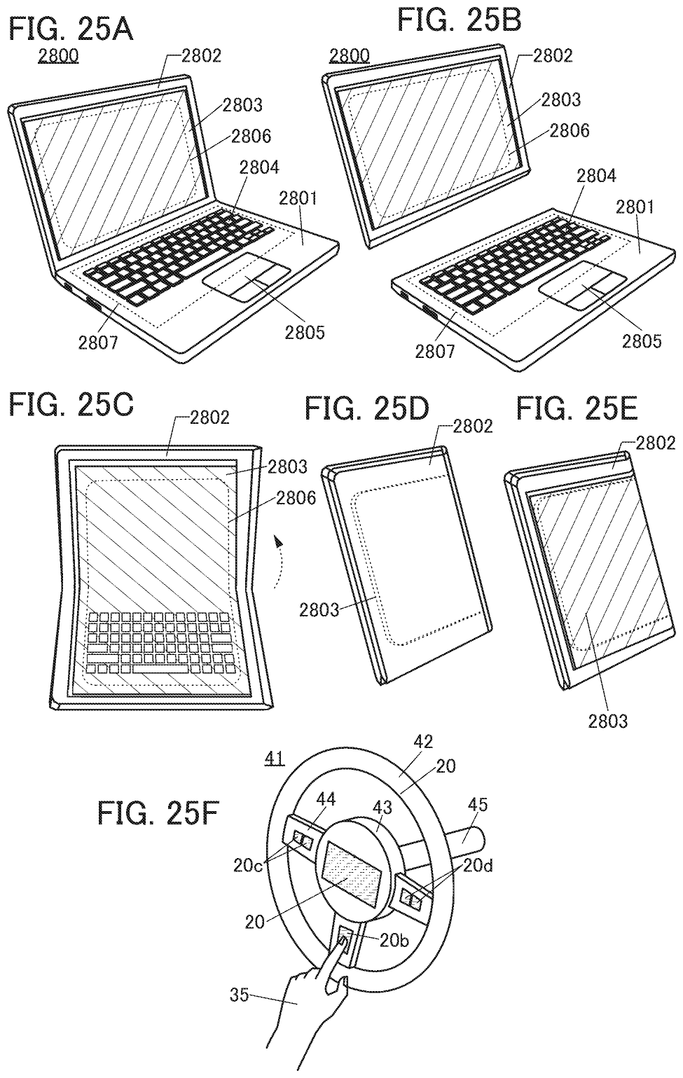

A personal computer 2800 illustrated in FIG. 25A includes a housing 2801, a housing 2802, a display portion 2803, a keyboard 2804, a pointing device 2805, and the like. A secondary battery 2807 is provided inside the housing 2801 and a secondary battery 2806 is provided inside the housing 2802. The display portion 2803 is the display apparatus of one embodiment of the present invention, and has a touch panel function. As illustrated in FIG. 25B, the housing 2801 and the housing 2802 of the personal computer 2800 can be separated and the housing 2802 can be used alone as a tablet terminal.

In a variation example of a personal computer illustrated in FIG. 25C, a flexible display is employed for the display portion 2803. With use of a flexible film as an exterior body, the secondary battery 2806 can be a bendable secondary battery. Accordingly, the housing 2802, the display portion 2803, and the secondary battery 2806 can be used in a bent state as illustrated in FIG. 25C. At this time, part of the display portion 2803 can also be used as a keyboard as illustrated in FIG. 25C.

Furthermore, the housing 2802 can be folded so that the display portion 2803 is placed inward as illustrated in FIG. 25D, and the housing 2802 can be folded so that the display portion 2803 faces outward as illustrated in FIG. 25E.

FIG. 25F is a perspective view illustrating a steering wheel of a vehicle. A steering wheel 41 includes a rim 42, a hub 43, spokes 44, a shaft 45, and the like. A display portion 20 is provided on the surface of the hub 43. The display apparatus of one embodiment of the present invention can be used for the display portion 20. among the three spokes 44, the spoke 44 positioned on the lower side is provided with a light-emitting and light-receiving portion 20b; the spoke 44 positioned on the left side is provided with a plurality of light-emitting and light-receiving portions 20c; and the spoke 44 positioned on the right side is provided with a plurality of light-emitting and light-receiving portions 20d. When a driver holds a finger of a hand 35 over the light-emitting and light-receiving portion 20b, information on a fingerprint of the driver is acquired, and authentication can be performed with the information. Touching the light-emitting and light-receiving portion 20c, the light-emitting and light-receiving portion 20d, and the like, the driver can operate systems such as a navigation system, an audio system, and a call system provided in the vehicle. In addition, a variety of operations such as adjustment of a rearview mirror and a sideview mirror, turning on/off of an interior light, adjustment of luminance, and opening/closing a window are possible.

This embodiment can be combined with any of the other embodiments as appropriate.

### REFERENCE NUMERALS

20b: light-emitting and light-receiving portion, 20c: light-emitting and light-receiving portion, 20d: light-emitting and light-receiving portion, 20: display portion, 35: hand, 41: handle, 42: rim, 43: hub, 44: spoke, 45: shaft, 100A: display apparatus, 100B: display apparatus, 100C: display apparatus, 100D: display apparatus, 100E: display apparatus, 100F: display apparatus, 100G: display apparatus, 100: display apparatus, 101: layer, 103: pixel, 110a: subpixel, 110B: subpixel, 110b: subpixel, 110c: subpixel, 110d: subpixel, 110G: subpixel, 110R: subpixel, 110: pixel, 111a: pixel electrode, 111b: pixel electrode, 111: pixel electrode, 113A: EL film, 113: EL layer, 114: common layer, 115: common electrode, 117: light-blocking layer, 118A: sacrificial film, 118: sacrificial layer, 119A: sacrificial film, 119: sacrificial layer, 120: substrate, 122: resin layer, 123: conductive layer, 124a: pixel, 124b: pixel, 125A: insulating film, 125: insulating layer, 126: conductive layer, 127A: insulating film, 127: insulating layer, 128: layer, 129: conductive layer, 130: light-emitting device, 131: protective layer, 132B: coloring layer, 132G: coloring layer, 132R: coloring layer, 133: lens array, 134: insulating layer, 138: region, 139: region, 140: connection portion, 142: adhesive layer, 151: substrate, 152: substrate, 153: insulating layer, 162: display portion, 164: circuit, 165: wiring, 166: conductive layer, 172: FPC, 173: IC, 190: resist mask, 191: mask, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 700A: electronic device, 700B: electronic device, 721: housing, 723: mounting portion, 727: earphone portion, 750: earphone, 751: display panel, 753: optical member, 756: display region, 757: frame, 758: nose pad, 772: lower electrode, 785: layer, 786a: EL layer, 786b: EL layer, 786: EL layer, 788: upper electrode, 800A: electronic device, 800B: electronic device, 820: display portion, 821: housing, 822: communication portion, 823: mounting portion, 824: control portion, 825: image capturing portion, 827: earphone portion, 832: lens, 2800: personal computer, 2801: housing, 2802: housing, 2803: display portion, 2804: keyboard, 2805: pointing device, 2806: secondary battery, 2807: secondary battery, 4411: light-emitting layer, 4412: light-emitting layer, 4413: light-emitting layer, 4420: layer, 4421: layer, 4422: layer, 4430: layer, 4431: layer, 4432: layer, 4440: charge-generation layer, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: control key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a first light-emitting device, a second light-emitting device, a first insulating layer, a first coloring layer, and a second coloring layer,
wherein the first light-emitting device comprises a first pixel electrode, a first EL layer over the first pixel electrode, and a common electrode over the first EL layer,
wherein the second light-emitting device comprises a second pixel electrode, a second EL layer over the second pixel electrode, and the common electrode over the second EL layer,
wherein the first coloring layer overlaps with the first light-emitting device,
wherein the second coloring layer overlaps with the second light-emitting device,
wherein the second coloring layer and the first coloring layer transmit light of different colors,
wherein the first EL layer and the second EL layer have the same structure and are separated from each other,
wherein an end portion of the first EL layer is positioned over the first pixel electrode,
wherein an end portion of the second EL layer is positioned over the second pixel electrode,
wherein the first insulating layer covers side surfaces of the first pixel electrode, the second pixel electrode, the first EL layer, and the second EL layer, and
wherein the common electrode is positioned over the first insulating layer.

2. The display apparatus according to claim 1,
wherein the first EL layer comprises a first light-emitting unit over the first pixel electrode, a first charge-generation layer over the first light-emitting unit, and a second light-emitting unit over the first charge-generation layer, and
wherein the second EL layer comprises a third light-emitting unit over the second pixel electrode, a second charge-generation layer over the third light-emitting unit, and a fourth light-emitting unit over the second charge-generation layer.

3. The display apparatus according to claim 1, further comprising a second insulating layer,
wherein the first insulating layer comprises an inorganic material, and
wherein the second insulating layer comprises an organic material and overlaps with the side surfaces of the first pixel electrode, the second pixel electrode, the first EL layer, and the second EL layer with the first insulating layer therebetween.

4. The display apparatus according to claim 1,
wherein the first light-emitting device comprises a common layer between the first EL layer and the common electrode,
wherein the second light-emitting device comprises the common layer between the second EL layer and the common electrode, and
wherein the common layer comprises at least one of a hole-injection layer, a hole-transport layer, a hole-blocking layer, an electron-blocking layer, an electron-transport layer, and an electron-injection layer.

5. The display apparatus according to claim 1,
wherein the first EL layer comprises a first light-emitting material emitting blue light and a second light-emitting material emitting light with a longer wavelength than blue light.

6. The display apparatus according to claim 1,
wherein the first insulating layer is in contact with the side surface of the first pixel electrode and the side surface of the second pixel electrode.

7. A display module comprising:
the display apparatus according to claim 1; and
at least one of a connector and an integrated circuit.

8. An electronic device comprising:
the display module according to claim 7; and
at least one of a housing, a battery, a camera, a speaker, and a microphone.

9. A method for fabricating a display apparatus, comprising:
forming a first pixel electrode and a second pixel electrode over an insulating surface;
forming an EL film over the first pixel electrode and the second pixel electrode;
forming a sacrificial film over the EL film;
processing the EL film and the sacrificial film to form a first EL layer having an end portion over the first pixel electrode, a first sacrificial layer over the first EL layer, a second EL layer having an end portion over the second pixel electrode, and a second sacrificial layer over the second EL layer;
forming a first insulating film covering at least a side surface of the first pixel electrode, a side surface of the second pixel electrode, a side surface of the first EL layer, a side surface of the second EL layer, a side surface and a top surface of the first sacrificial layer, and a side surface and a top surface of the second sacrificial layer;
processing the first insulating film to form a first insulating layer covering at least the side surface of the first pixel electrode, the side surface of the second pixel electrode, the side surface of the first EL layer, and the side surface of the second EL layer;
removing the first sacrificial layer and the second sacrificial layer;
forming a common electrode over the first EL layer and the second EL layer; and
placing, over the common electrode, a first coloring layer overlapping with the first EL layer and a second coloring layer overlapping with the second EL layer.

10. The method for fabricating a display apparatus, according to claim 9, further comprising:
forming the first insulating film using an inorganic material;
forming a second insulating film using an organic material over the first insulating film after the first insulating film is formed; and
processing the second insulating film to form a second insulating layer overlapping with the side surfaces of the first pixel electrode, the second pixel electrode, the first EL layer, and the second EL layer with the first insulating film therebetween.

11. The method for fabricating a display apparatus, according to claim 10,
wherein a photosensitive resin is used as the organic material.

12. The method for fabricating a display apparatus, according to claim 9, further comprising:
forming at least one of a hole-injection layer, a hole-transport layer, a hole-blocking layer, an electron-blocking layer, an electron-transport layer, and an electron-injection layer as a common layer over the first EL layer and the second EL layer, before the common electrode is formed.
